(19) United States
(12) Patent Application Publication
(10) Pub. No.: US 2025/0149298 A1
(43) Pub. Date: May 8, 2025

(54) PLASMA PROCESSING APPARATUS

(71) Applicant: Tokyo Electron Limited, Tokyo (JP)

(72) Inventors: Nozomu NAGASHIMA, Miyagi (JP); Daisuke YOSHIKOSHI, Miyagi (JP); Kunihiko YAMAGATA, Miyagi (JP)

(73) Assignee: Tokyo Electron Limited, Tokyo (JP)

(21) Appl. No.: 19/003,836

(22) Filed: Dec. 27, 2024

Related U.S. Application Data
(63) Continuation of application No. PCT/JP2023/005254, filed on Feb. 15, 2023.
(60) Provisional application No. 63/356,713, filed on Jun. 29, 2022.

(51) Int. Cl. H01J 37/32

(52) U.S. Cl. CPC H01J 37/32174; H01J 37/3211; H01J 37/32146

(57) ABSTRACT

A plasma processing apparatus comprises a plasma processing chamber, a substrate support, an electrode or an antenna, a high frequency power supply, a consuming member, an electricity storage unit and a power receiving coil. The electrode or an antenna is disposed such that a space within the plasma processing chamber is located between the electrode or the antenna and the substrate support. The high frequency power supply is configured to generate high frequency power and is electrically connected to the substrate support, the electrode or the antenna. The power consuming member is disposed within the plasma processing chamber or the substrate support. The electricity storage unit is electrically connected to the power consuming member. The power receiving coil is electrically connected to the electricity storage unit and capable of receiving power from a power transmitting coil by electromagnetic induction coupling.

### CROSS-REFERENCE TO RELATED APPLICATIONS

This application is a bypass continuation application of International Application No. PCT/JP2023/005254 having an international filing date of Feb. 15, 2023 and designating the United States, the International Application being based upon and claiming the benefit of priority from the U.S. Provisional Patent Application No. 63/356,713 filed on Jun. 29, 2022, the entire contents of each are incorporated herein by reference.

### TECHNICAL FIELD

An exemplary embodiment of the present disclosure relates to a plasma processing apparatus.

### BACKGROUND

The plasma processing apparatus is used in the plasma processing. The plasma processing apparatus includes a chamber and a substrate support (mounting table) disposed within the chamber. The substrate support has a base (lower electrode) and an electrostatic chuck that holds a substrate. A temperature adjustment element (for example, a heater) for adjusting the temperature of the substrate is provided inside the electrostatic chuck. In addition, a filter is provided between the temperature adjustment element and a power supply for the temperature adjustment element to attenuate or block high frequency noise entering lines such as power-feeding lines and/or signal wires from high frequency electrodes and/or other electrical members within the chamber. One type of such plasma processing apparatus is disclosed in Japanese Laid-open Patent Publication No. 2015-173027.

### SUMMARY

An exemplary embodiment of the present disclosure provides a technology for suppressing the propagation of high frequency noise to a power supply external to a plasma processing apparatus.

According to an exemplary embodiment, a plasma processing apparatus is provided. The plasma processing apparatus comprises a plasma processing chamber, a substrate support, an electrode or an antenna, a high frequency power supply, at least one power consuming member, at least one electricity storage unit and at least one power receiving coil. The substrate support is disposed within the plasma processing chamber. The electrode or an antenna is disposed outside a plasma processing space within the plasma processing chamber such that a space within the plasma processing chamber is located between the electrode or the antenna and the substrate support. The high frequency power supply is configured to generate high frequency power and is electrically connected to the substrate support, the electrode or the antenna. The at least one power consuming member is disposed within the plasma processing chamber or the substrate support. The at least one electricity storage unit is electrically connected to the at least one power consuming member. The at least one power receiving coil is electrically connected to the at least one electricity storage unit and capable of receiving power from at least one power transmitting coil by electromagnetic induction coupling.

### BRIEF DESCRIPTION OF THE DRAWINGS

FIG. 1 is a diagram illustrating an example of a configuration of a plasma processing system.

FIG. 2 is a diagram illustrating an example of a configuration of a capacitively coupled plasma processing apparatus.

FIG. 3 is a diagram schematically illustrating a plasma processing apparatus according to one exemplary embodiment.

FIG. 4 is a diagram schematically illustrating a plasma processing apparatus according to another exemplary embodiment.

FIG. 5 is a diagram schematically illustrating a plasma processing apparatus according to yet another exemplary embodiment.

FIG. 6 is a diagram schematically illustrating a plasma processing apparatus according to yet another exemplary embodiment.

FIG. 7 is a diagram schematically illustrating a plasma processing apparatus according to yet another exemplary embodiment.

FIG. 8 is a diagram illustrating a power transmission unit according to one exemplary embodiment.

FIG. 9 is a diagram illustrating a power transmitting coil unit and a power receiving coil unit according to one exemplary embodiment.

FIG. 10 is a diagram illustrating a power transmitting coil unit and a power receiving coil unit according to one exemplary embodiment.

FIG. 11 is a diagram illustrating a power transmitting coil unit and a power receiving coil unit according to one exemplary embodiment.

FIG. 12 is a graph showing the impedance characteristics of a power receiving coil unit according to one exemplary embodiment.

FIG. 13 is a diagram illustrating an RF filter according to one exemplary embodiment.

FIG. 14 is a diagram illustrating a rectifying and smoothing unit according to one exemplary embodiment.

FIG. 15 is a diagram illustrating an RF filter according to one exemplary embodiment.

FIG. 16 is a diagram illustrating a communication unit of a power transmission unit and a communication unit of a rectifying and smoothing unit according to one exemplary embodiment.

FIG. 17 is a diagram schematically illustrating a plasma processing apparatus according to yet another exemplary embodiment.

FIG. 18 is a diagram schematically illustrating a plasma processing apparatus according to yet another exemplary embodiment.

FIG. 19 is a diagram illustrating a communication unit of a power transmission unit and a communication unit of a rectifying and smoothing unit according to another exemplary embodiment.

FIG. 20 is a diagram schematically illustrating a plasma processing apparatus according to yet another exemplary embodiment.

FIG. 21 is a diagram schematically illustrating a plasma processing apparatus according to yet another exemplary embodiment.

FIG. 22 is a diagram schematically illustrating a plasma processing apparatus according to yet another exemplary embodiment.

Each of FIGS. 23A and 23B is a diagram illustrating an electricity storage unit according to one exemplary embodiment.

FIG. 24 is a diagram illustrating a voltage control converter according to one exemplary embodiment.

FIG. 25 is a diagram illustrating a constant voltage controller according to one exemplary embodiment.

FIG. 26 is a diagram illustrating a constant voltage controller according to another exemplary embodiment.

FIG. 27 is a diagram schematically illustrating a plasma processing apparatus according to yet another exemplary embodiment.

FIG. 28 is a diagram schematically illustrating a plasma processing apparatus according to yet another exemplary embodiment.

FIG. 29 is a diagram schematically illustrating a plasma processing apparatus according to yet another exemplary embodiment.

FIG. 30 is a diagram illustrating the disposition of a rectifying and smoothing unit according to one exemplary embodiment.

FIG. 31 is a diagram illustrating the disposition of a rectifying and smoothing unit according to another exemplary embodiment.

FIG. 32 is a diagram schematically illustrating a plasma processing apparatus according to yet another exemplary embodiment.

FIG. 33 is a diagram schematically illustrating a plasma processing apparatus according to yet another exemplary embodiment.

FIG. 34 is a diagram illustrating the disposition of a rectifying and smoothing unit according to yet another exemplary embodiment.

FIG. 35 is a diagram illustrating the disposition of a rectifying and smoothing unit according to yet another exemplary embodiment.

FIG. 36 is a diagram illustrating the disposition of a rectifying and smoothing unit according to yet another exemplary embodiment.

FIG. 37 is a diagram illustrating the disposition of a rectifying and smoothing unit according to yet another exemplary embodiment.

FIG. 38 is a diagram illustrating the disposition of a rectifying and smoothing unit according to yet another exemplary embodiment.

FIG. 39 is a diagram illustrating the disposition of a rectifying and smoothing unit according to yet another exemplary embodiment.

FIG. 40 is a diagram illustrating an exemplary embodiment for reducing a line-to-line potential difference due to conductive noise.

FIG. 41 is a diagram illustrating an exemplary embodiment for reducing the line-to-line potential difference due to conductive noise.

FIG. 42 is a diagram illustrating an exemplary embodiment for reducing the line-to-line potential difference due to conductive noise.

FIG. 43 is a diagram illustrating an exemplary embodiment for reducing the line-to-line potential difference due to conductive noise.

FIG. 44 is a diagram illustrating a rectifying and smoothing unit according to another exemplary embodiment.

FIG. 45 is a diagram illustrating a rectifying and smoothing unit according to yet another exemplary embodiment.

FIG. 46 is a diagram illustrating a rectifying and smoothing unit according to yet another exemplary embodiment.

FIG. 47 is a diagram illustrating a rectifying and smoothing unit and a constant voltage controller according to another exemplary embodiment.

FIG. 48 is a timing chart of an example of a signal output from each unit of the rectifying and smoothing unit and an output voltage in a power receiving coil unit.

FIG. 49 is an exemplary timing chart related to the constant voltage controller shown in FIG. 47.

FIG. 50 is an exemplary timing chart related to the constant voltage controller shown in FIG. 47.

FIG. 51 is a diagram schematically illustrating a plasma processing apparatus according to yet another exemplary embodiment.

FIG. 52 is a diagram illustrating an electricity storage unit in a plasma processing apparatus according to yet another exemplary embodiment.

FIG. 53 is a diagram schematically illustrating a plasma processing apparatus according to yet another exemplary embodiment.

FIG. 54 is a diagram illustrating an electricity storage unit in a plasma processing apparatus according to yet another exemplary embodiment.

FIG. 55 is a diagram schematically illustrating a plasma processing apparatus according to yet another exemplary embodiment.

FIG. 56 is a diagram illustrating a connection of a plurality of voltage control converters in a plasma processing apparatus according to yet another exemplary embodiment.

FIG. 57 is a diagram schematically illustrating a plasma processing apparatus according to yet another exemplary embodiment.

FIG. 58 is a diagram schematically illustrating a plasma processing apparatus according to yet another exemplary embodiment.

FIG. 59 is a diagram illustrating a connection of a plurality of voltage control converters in a plasma processing apparatus according to yet another exemplary embodiment.

FIG. 60 is a diagram schematically illustrating a plasma processing apparatus according to yet another exemplary embodiment.

FIG. 61 is a diagram schematically illustrating a plasma processing apparatus according to yet another exemplary embodiment.

FIG. 62 is a diagram illustrating a rectifying and smoothing unit according to yet another exemplary embodiment.

FIG. 63 is a diagram schematically illustrating a plasma processing apparatus according to yet another exemplary embodiment.

FIG. 64 is a diagram schematically illustrating a rectifying and smoothing unit according to yet another exemplary embodiment.

FIG. 65 is a diagram illustrating a power receiving coil unit and a power transmitting coil unit in a plasma processing apparatus according to yet another exemplary embodiment.

FIG. 66 is a diagram illustrating a power receiving coil unit and a power transmitting coil unit in a plasma processing apparatus according to yet another exemplary embodiment.

FIG. 67 is a diagram illustrating a power receiving coil unit and a power transmitting coil unit in a plasma processing apparatus according to yet another exemplary embodiment.

FIG. 68 is a flowchart of an electricity storage method of an electricity storage unit according to one exemplary embodiment.

### DETAILED DESCRIPTION

Hereinafter, various exemplary embodiments will be described in detail with reference to the drawings, in which the same or corresponding portions are designated by the same reference numerals.

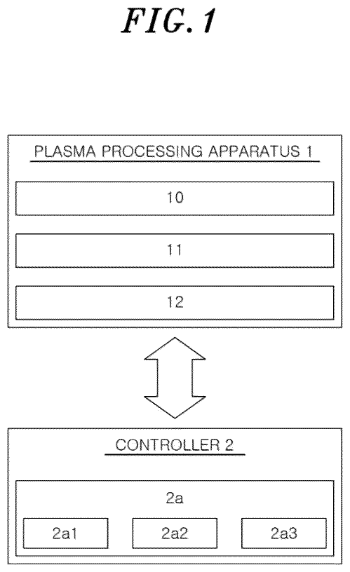

FIG. 1 is a diagram illustrating an example of a configuration of a plasma processing system. In an embodiment, the plasma processing system includes a plasma processing apparatus 1 and a controller (control circuitry, processing circuitry) 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas inlet for supplying at least one processing gas to the plasma processing space and at least one gas outlet for discharging the gas from the plasma processing space. The gas inlet is connected to a gas supply portion 20 to be described later, and the gas outlet is connected to an exhaust system 40 to be described later. The substrate support 11 is disposed within the plasma processing space and has a substrate support surface for supporting a substrate.

The plasma generator 12 is configured to generate a plasma from at least one processing gas supplied into the plasma processing space. The plasma formed in the plasma processing space may be a capacitively coupled plasma (CCP), an inductively coupled plasma (ICP), an electron-cyclotron-resonance (ECR) plasma, a helicon wave excited plasma (HWP), or a surface wave plasma (SWP). Further, various types of plasma generators including an alternating current (AC) plasma generator and a direct current (DC) plasma generator may be used. In an embodiment, an AC signal (AC power) used in the AC plasma generator has a frequency in a range of 100 kHz to 10 GHz. Thus, the AC signal includes a radio frequency (RF) signal and a microwave signal. In an embodiment, the RF signal has a frequency in a range of 100 kHz to 150 MHz.

The controller (processing circuitry) 2 processes a computer executable instruction that causes the plasma processing apparatus 1 to execute various processes described in an embodiment of the present disclosure. The controller 2 may be configured to control each element of the plasma processing apparatus 1 so as to execute various processes described herein. In an embodiment, a part or all of the controller 2 may be included in the plasma processing apparatus 1. The controller 2 may include a processor 2a1, a memory unit 2a2, and a communication interface 2a3. The controller 2 is realized by, for example, a computer 2a. The processor 2a1 may be configured to perform various control operations by reading out a program from the memory unit 2a2 and executing the read out program. This program may be stored in advance in the memory unit 2a2, or may be acquired via a medium when necessary. The acquired program is stored in the memory unit 2a2, and is read out from the memory unit 2a2 and executed by the processor 2a1. The medium may be any of various memory media readable by the computer 2a, or may be a communication line connected to the communication interface 2a3. The processor 2a1 may be a central processing unit (CPU). The memory unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

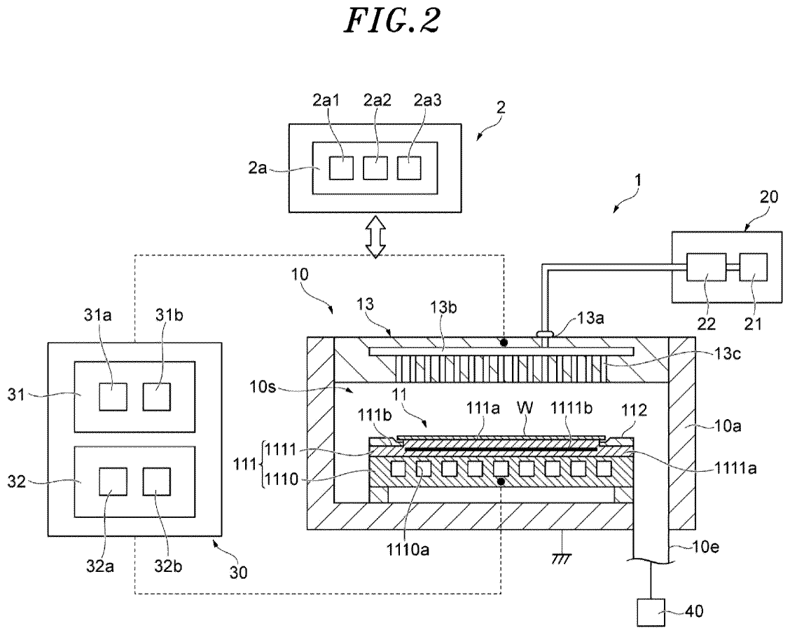

Hereinafter, the configuration example of a capacitively coupled plasma processing apparatus as an example of the plasma processing apparatus 1 will be described. FIG. 2 is a diagram illustrating an example of a configuration of a capacitively coupled plasma processing apparatus.

The capacitively coupled plasma processing apparatus 1 includes the plasma processing chamber 10, a gas supply portion 20, a power supply 30, and an exhaust system 40. Further, the plasma processing apparatus 1 includes the substrate support 11 and a gas introduction portion. The introduction portion is configured to introduce at least one processing gas into the plasma processing chamber 10. The introduction portion includes a shower head 13. The substrate support 11 is disposed within the plasma processing chamber 10. The shower head 13 is disposed above the substrate support 11. In an embodiment, the shower head 13 forms at least portion of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central area 111a for supporting a substrate W, and an annular area 111b for supporting the ring assembly 112. The wafer is an example of the substrate W. The annular area 111 b of the main body 111 surrounds the central area 111a of the main body 111 in a plan view. The substrate W is disposed on the central area 111a of the main body 111, and the ring assembly 112 is disposed on the annular area 111b of the main body 111 to surround the substrate W on the central area 111a of the main body 111. Accordingly, the central area 111a is also called a substrate support surface for supporting the substrate W, and the annular area 111 b is also called a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode (also called an adsorption electrode, a chuck electrode, or a clamp electrode) 1111b disposed within the ceramic member 1111a. The ceramic member 1111a has the central area 111a. In an embodiment, the ceramic member 1111a also has the annular area 111b. Further, other members surrounding the electrostatic chuck 1111, such as an annular electrostatic chuck or an annular insulating member, may be provided in the annular area 111b. In this connection, the ring assembly 112 may be disposed on the annular electrostatic chuck or the annular insulating member, and may be disposed on both the electrostatic chuck 1111 and the annular insulating member. Further, at least one RF/DC electrode coupled to an RF power supply 31 and/or a DC power supply 32, which will be described later, may be disposed within the ceramic member 1111a. In this connection, at least one RF/DC electrode functions as a lower electrode. When a bias RF signal and/or a DC signal, which will be described later, is supplied to at least one RF/DC electrode, the RF/DC electrode is also referred to as a bias electrode. Further, the conductive member of the base 1110 and at least one RF/DC electrode may function as a plurality of lower electrodes. Further, the electrostatic electrode 1111b may function as a lower electrode. Accordingly, the substrate support 11 includes at least one lower electrode.

The ring assembly 112 includes one or more annular members. In an embodiment, the one or more annular members include one or more edge rings and at least one cover ring. The edge ring is formed of a conductive or insulating material, and the cover ring is formed of an insulating material.

Further, the substrate support 11 may include a temperature control module configured to adjust at least one of the electrostatic chuck 1111, the ring assembly 112, and the substrate W to a target temperature. The temperature control module may include a heater, a heat transfer medium, a flow path 1110a, or a combination thereof. A heat transfer fluid such as brine or gas flows through the flow path 1110a. In an embodiment, the flow path 1110a is formed in the base 1110, and one or more heaters are disposed within the ceramic member 1111a of the electrostatic chuck 1111. Further, the substrate support 11 may include a heat transfer gas supply portion configured to supply heat transfer gas to a gap between the back surface of the substrate W and the central area 111a.

The shower head 13 is configured to introduce at least one processing gas from the gas supply portion 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and then is introduced from the plurality of gas introduction ports 13c into the plasma processing space 10s. Further, the shower head 13 includes at least one upper electrode. In addition to the shower head 13, the gas introduction portion may include one or more side gas injectors (SGI) installed in one or more openings formed in the side wall 10a.

The gas supply portion 20 may include at least one gas source 21 and at least one flow controller 22. In an embodiment, the gas supply portion 20 is configured to supply at least one processing gas from a corresponding gas source 21 through a corresponding flow controller 22 to the shower head 13. The flow controller 22 may include, for example, a mass flow controller or a pressure-controlled flow controller. Further, the gas supply portion 20 may include at least one flow modulation device that modulates or pulses the flow rate of at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. Thereby, plasma is formed from at least one processing gas supplied to the plasma processing space 10s. Accordingly, the RF power supply 31 may function as at least a portion of the plasma generator 12. Further, by supplying a bias RF signal to at least one lower electrode, a bias potential may be generated on the substrate W, and ion components in the formed plasma may be attracted into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In an embodiment, the source RF signal has a frequency within the range of 10 MHz to 150 MHZ. In an embodiment, the first RF generator 31a may be configured to generate a plurality of source RF signals having different frequencies. One or more generated source RF signals are supplied to at least one lower electrode and/or at least one upper electrode.

The second RF generator 31b is coupled to at least one lower electrode via at least one impedance matching circuit, and is configured to generate a bias RF signal (bias RF power). The frequency of the bias RF signal may be equal to or different from the frequency of the source RF signal. In an embodiment, the bias RF signal has a frequency that is lower than the frequency of the source RF signal. In an embodiment, the bias RF signal has a frequency within the range of 100 kHz to 60 MHz. In an embodiment, the second RF generator 31b may be configured to generate a plurality of bias RF signals having different frequencies. One or more generated bias RF signals are supplied to at least one lower electrode. Further, in various embodiments, at least one of the source RF signal and the bias RF signal may be pulsed.

The power supply 30 may also include the DC power supply 32 coupled to the plasma processing chamber 10. The DC power supply 32 includes a first DC generator 32a and a second DC generator 32b. In one embodiment, the first DC generator 32a is connected to at least one lower electrode and generates a first DC signal. The generated first DC signal is applied to at least one lower electrode. In one embodiment, the second DC generator 32b is connected to at least one upper electrode and generates a second DC signal. The generated second DC signal is applied to at least one upper electrode.

In various embodiments, the first DC signal or the second DC signal may be pulsed. In this connection, a sequence of voltage pulses is applied to at least one lower electrode and/or to at least one upper electrode. The voltage pulse may have a rectangular, trapezoidal, or triangular pulse waveform, or a combination of these pulse waveforms. In one embodiment, a waveform generator for generating a sequence of voltage pulses based on DC signals is connected between the first DC generator 32a and at least one lower electrode. Thus, the first DC generator 32a and the waveform generator are included in a voltage pulse generator. When the second DC generator 32b and the waveform generator are included in the voltage generator, the voltage pulse generator is connected to at least one upper electrode. The voltage pulses may have positive or negative polarity. The sequence of voltage pulses may also include one or more positive voltage pulses and one or more negative voltage pulses within one cycle. Further, the first DC generator 32a and the second DC generator 32b may be provided in addition to the RF power supply 31, or the first DC generator 32 a may replace the second RF generator 31b.

The exhaust system 40 may be, for example, connected to a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

Further, in the capacitively coupled plasma processing apparatus 1, the upper electrode is disposed so that the plasma processing space is located between the upper electrode and the substrate support 11. A high frequency power supply, such as the first RF generator 31a, is electrically connected to the upper electrode or the lower electrode within the substrate support 11. When the plasma processing apparatus 1 is an inductively coupled plasma processing apparatus, the antenna is disposed so that the plasma processing space is located between the antenna and the substrate support 11. The high frequency power supply, such as the first RF generator 31a, is electrically connected to the antenna. When the plasma processing apparatus 1 is a plasma processing apparatus that generates plasma by surface waves such as microwaves, the antenna is disposed so that the plasma processing space is located between the antenna and the substrate support 11. A high frequency power supply, such as the first RF generator 31a, is electrically connected to the antenna via a waveguide.

Hereinafter, plasma processing apparatuses according to various exemplary embodiments will be described. Each of the plasma processing apparatuses described below is configured to supply power to at least one power consuming member in the chamber 10 by wireless power feeding (electromagnetic inductive coupling) and may have the same configuration as the plasma processing apparatus 1.

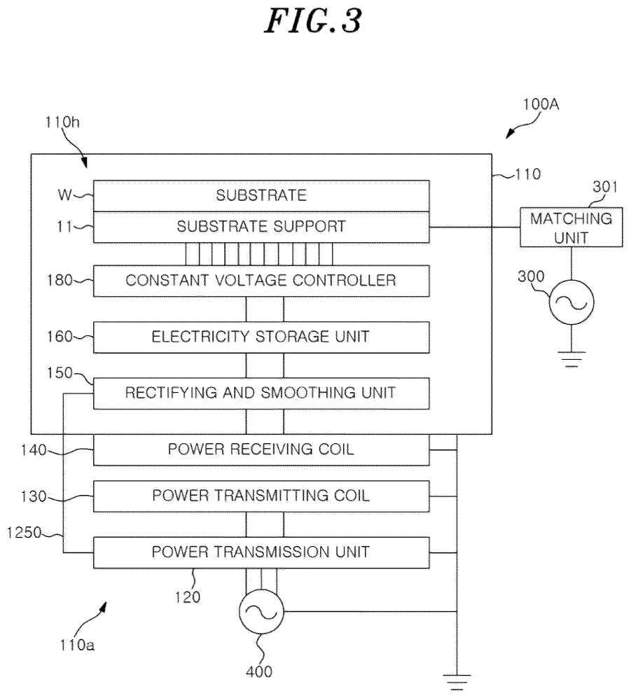

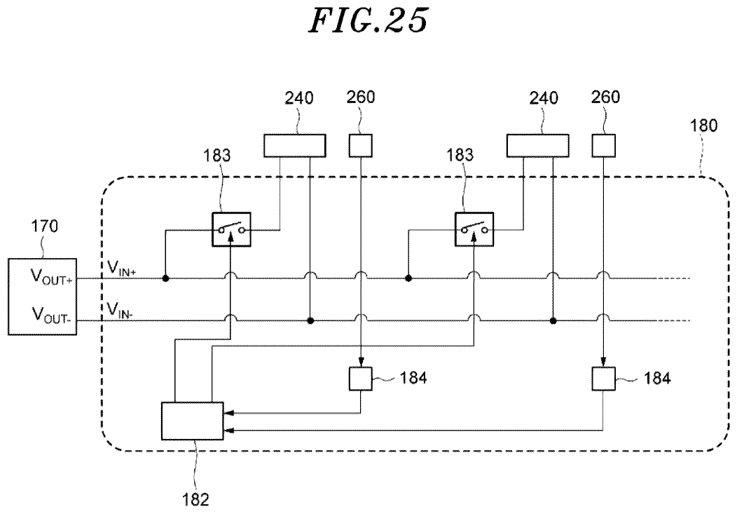

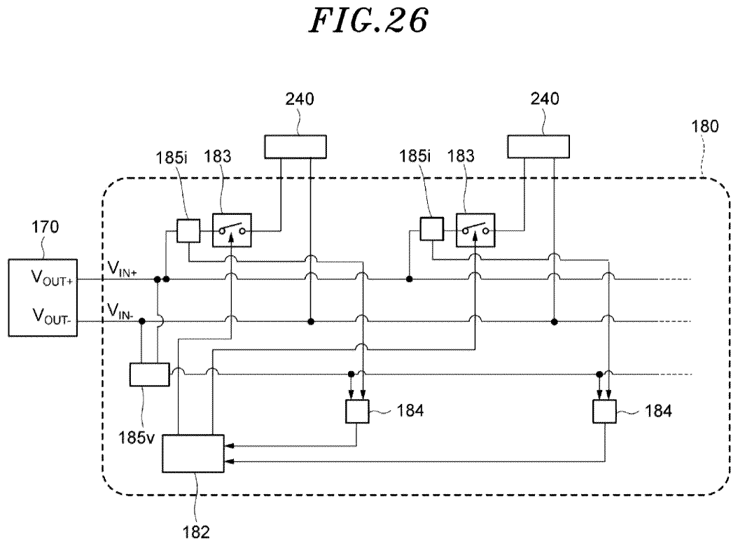

FIG. 3 is a diagram schematically illustrating a plasma processing apparatus according to one exemplary embodiment. A plasma processing apparatus 100A shown in FIG. 3 includes at least one high frequency power supply 300, a power receiving coil unit 140, an electricity storage unit 160, and at least one power consuming member 240 (see FIGS. 25 and 26). The plasma processing apparatus 100A may further include a power transmission unit 120, a power transmitting coil unit 130, a rectifying and smoothing unit 150, a constant voltage controller 180 (an example of a voltage controller), a ground frame 110, and a matching unit 301.

At least one high frequency power supply 300 includes the first RF generator 31a and/or the second RF generator 32a. At least one high frequency power supply 300 is electrically connected to the substrate support 11 via the matching unit 301. The matching unit 301 includes at least one impedance matching circuit.

The ground frame 110 includes the chamber 10 and is electrically grounded. The ground frame 110 electrically separates an internal space 110h (RF-Hot space) from an external space 110a (atmospheric space). The ground frame 110 surrounds the substrate support 11 disposed within the space 110h. In the plasma processing apparatus 100A, the rectifying and smoothing unit 150, the electricity storage unit 160, and the constant voltage controller 180 are disposed within the space 110h. In the plasma processing apparatus 100A, the power transmission unit 120, the power transmitting coil unit 130, and the power receiving coil unit 140 are disposed within the space 110a.

The devices disposed within the space 110a, that is, the power transmission unit 120, the power transmitting coil unit 130, and the power receiving coil unit 140, are covered by a metal housing made of a metal such as aluminum, and the metal housing is grounded. Thereby, this suppresses leakage of high frequency noise caused by high frequency power such as a first RF signal and/or a second RF signal. The metal housing and each power feeding line have an insulating distance therebetween. In the following description, high frequency power such as the first RF signal and/or the second RF signal propagating toward the power transmission unit 120 may be referred to as high frequency noise, common-mode noise, or conductive noise.

The power transmission unit 120 is electrically connected between an AC power supply 400 (for example, a commercial AC power supply) and the power transmitting coil unit 130. The power transmission unit 120 receives the frequency of AC power from the AC power supply 400 and converts the frequency of the AC power into a transmission frequency, thereby generating AC power having the transmission frequency, that is, transmission AC power.

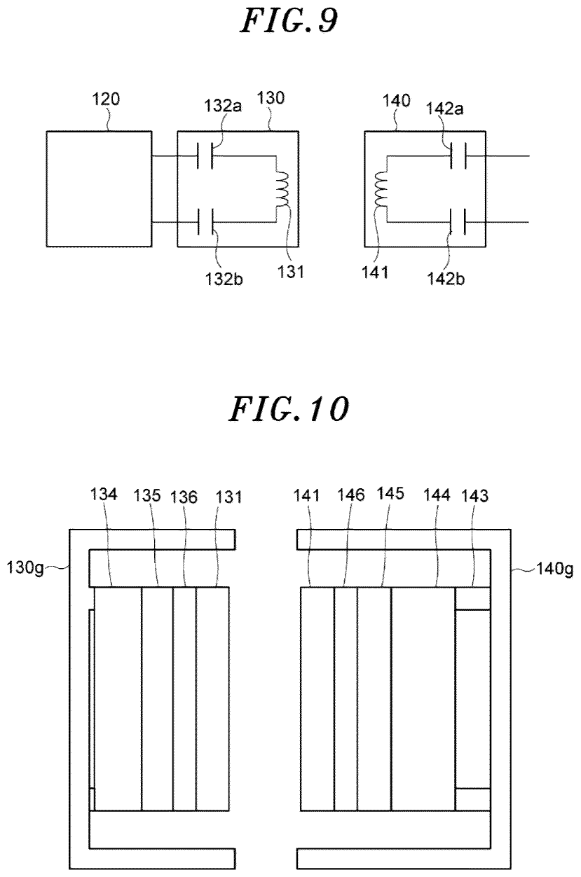

The power transmitting coil unit 130 includes a power transmitting coil 131 (see FIG. 9), which will be described later. The power transmitting coil 131 is electrically connected to power transmission unit 120. The power transmitting coil 131 receives the transmission AC power from the power transmission unit 120 and wirelessly transmits the transmission AC power to a power receiving coil 141.

The power receiving coil unit 140 includes a power receiving coil 141 (see FIG. 9) which will be described later. The power receiving coil 141 is electromagnetically inductively coupled to the power transmitting coil 131. Electromagnetic induction coupling includes magnetic field coupling and electric field coupling. In addition, the magnetic field coupling includes magnetic resonance. The distance between the power receiving coil 141 and the power transmitting coil 131 is set so as to suppress common mode noise (conductive noise). Further, the distance between the power receiving coil 141 and the power transmitting coil 131 is set to a distance that allows power feeding. The distance between the power receiving coil 141 and the power transmitting coil 131 is set so that the attenuation of high frequency power (that is, high frequency noise) between the power receiving coil 141 and the power transmitting coil 131 is below a threshold value and so that power from the power transmitting coil 131 is received by the power receiving coil 141. The threshold value of the attenuation is set to a value that may sufficiently prevent damage or malfunction of the power transmission unit 120. The threshold value of the attenuation is, for example, −20 dB. The transmission AC power received by the power receiving coil unit 140 is output to the rectifying and smoothing unit 150.

The rectifying and smoothing unit 150 is electrically connected between the power receiving coil unit 140 and the electricity storage unit 160. The rectifying and smoothing unit 150 generates DC power by full-wave rectification and smoothing of the AC power transmitted from the power receiving coil unit 140. The DC power generated by the rectifying and smoothing unit 150 is stored in the electricity storage unit 160. The electricity storage unit 160 is electrically connected between the rectifying and smoothing unit 150 and the constant voltage controller 180. The rectifying and smoothing unit 150 may generate DC power by half-wave rectification and smoothing of the AC power transmitted from the power receiving coil unit 140.

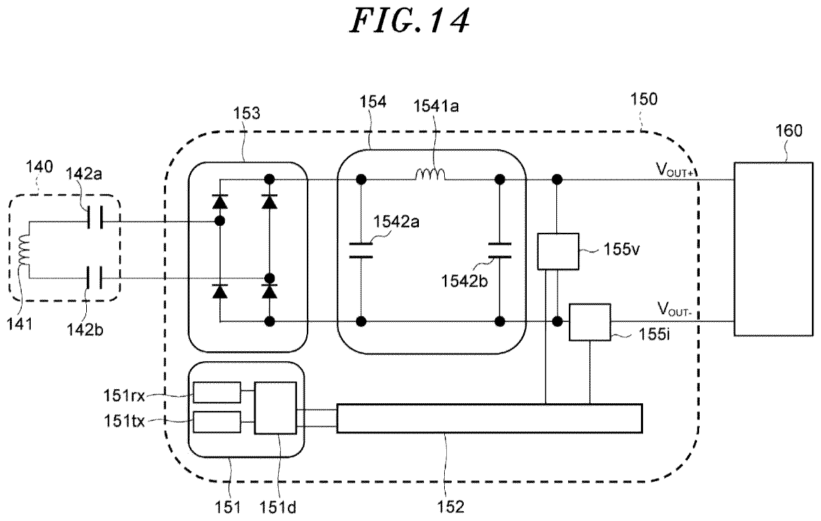

The rectifying and smoothing unit 150 and the power transmission unit 120 are electrically connected to each other by a signal line 1250. The rectifying and smoothing unit 150 transmits an instruction signal to the power transmission unit 120 via the signal line 1250. The instruction signal is a signal for instructing the power transmission unit 120 to supply transmission AC power or to stop supplying transmission AC power. The instruction signal may include a status signal, an abnormality detection signal, and a cooling control signal for the power transmitting coil unit 130 and the power receiving coil unit 140. The status signal is a value of the magnitude and/or phase of the voltage, current, power, etc. detected by a voltage detector 155v (see FIG. 14) and a current detector 155i (see FIG. 14) of the rectifying and smoothing unit 150. The abnormality detection signal is a signal for transmitting to the power transmission unit 120 the occurrence of a failure and/or an abnormal temperature in the rectifying and smoothing unit 150. The cooling control signal controls the cooling appliances provided in the power transmitting coil unit 130 and the power receiving coil unit 140. The cooling control signal controls the number of revolutions of a fan in the case of air cooling, for example. Further, in the case of liquid cooling, the flow rate and/or temperature of a coolant are controlled.

The constant voltage controller 180 applies a voltage to at least the power consuming member 240 using the power stored in the electricity storage unit 160. The constant voltage controller 180 may at least control the application of voltage to the power consuming member 240 and the stopping of the application.

In the plasma processing apparatus 100A, the power receiving coil 141 functions as a filter against high frequency noise caused by high frequency power such as the first RF signal and/or the second RF signal. Accordingly, the propagation of high frequency noise to the power supply outside the plasma processing apparatus is suppressed.

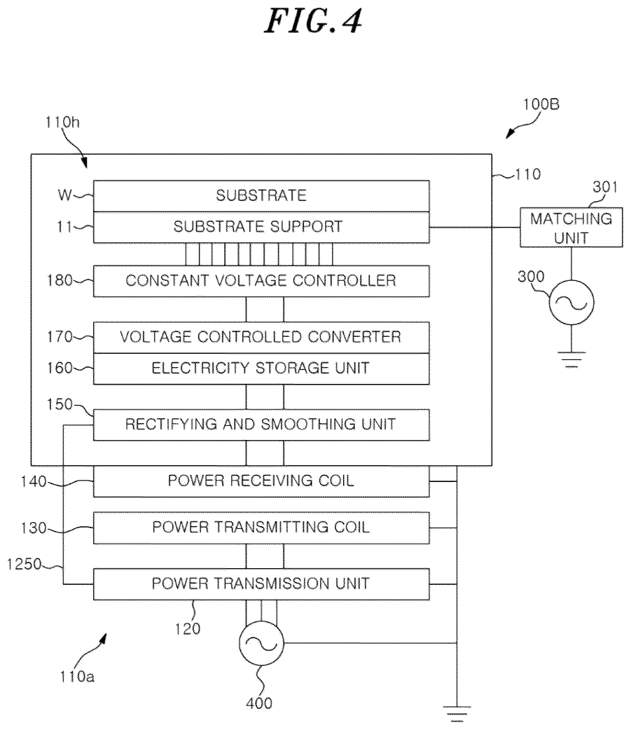

FIG. 4 is referred. FIG. 4 is a diagram schematically illustrating a plasma processing apparatus according to another exemplary embodiment. Hereinafter, a plasma processing apparatus 100B shown in FIG. 4 will be described from the viewpoint of its differences from the plasma processing apparatus 100A.

The plasma processing apparatus 100B further includes a voltage controlled converter 170. The voltage controlled converter 170 is a DC-DC converter, and is connected between the electricity storage unit 160 and the constant voltage controller 180. The voltage controlled converter 170 may be configured to input a constant output voltage to the constant voltage controller 180 even when a voltage fluctuation occurs in the electricity storage unit 160. Further, the voltage fluctuation in the electricity storage unit 160 may occur as a voltage drop or the like according to the stored power when the electricity storage unit 160 is configured with an electric double layer, for example.

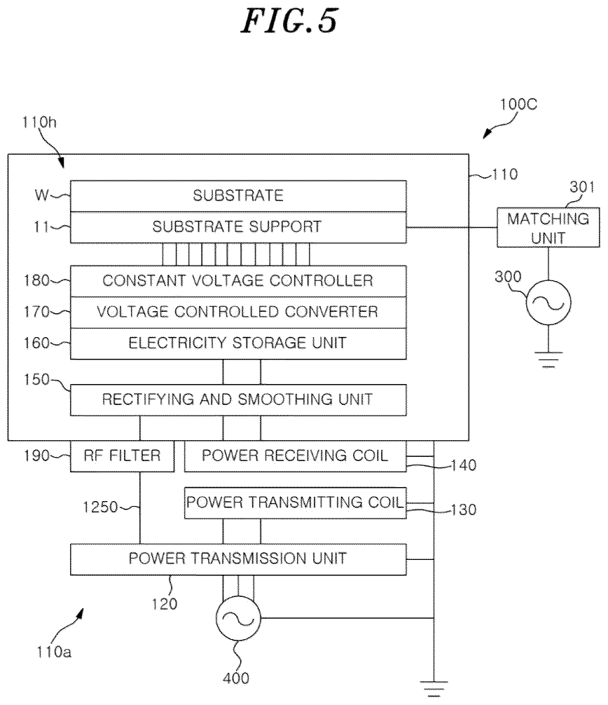

FIG. 5 is referred. FIG. 5 is a diagram schematically illustrating a plasma processing apparatus according to yet another exemplary embodiment. Hereinafter, a plasma processing apparatus 100C shown in FIG. 5 will be described from the viewpoint of its differences from the plasma processing apparatus 100B.

The plasma processing apparatus 100C further includes an RF filter 190. The RF filter 190 is connected between the rectifying and smoothing unit 150 and the power transmission unit 120. The RF filter 190 configures a portion of the signal line 1250. The RF filter 190 has the characteristic of suppressing the propagation of high frequency power (high frequency noise) via the signal line 1250. That is, the RF filter 190 includes a low-pass filter having a characteristic of having high impedance to high frequency noise (conductive noise) but passing an instruction signal of a relatively low frequency.

In the plasma processing apparatus 100C, the electricity storage unit 160, the voltage controlled converter 170, and the constant voltage controller 180 are integrated with one another. That is, the electricity storage unit 160, the voltage controlled converter 170, and the constant voltage controller 180 are all disposed within a single metal housing or formed on a single circuit board. This shortens the length of each of a pair of power feeding lines (positive line and negative line) connecting the electricity storage unit 160 and the voltage controlled converter 170 to each other. Furthermore, the lengths of the pair of power feeding lines connecting the electricity storage unit 160 and the voltage controlled converter 170 to each other may be made equal to each other. Furthermore, the length of each of the pair of power feeding lines (positive and negative lines) connecting the voltage controlled converter 170 and the constant voltage controller 180 to each other is shortened. Furthermore, the lengths of the pair of power feeding lines connecting the voltage controlled converter 170 and the constant voltage controller 180 to each other may be made equal to each other. Accordingly, malfunction and damage of a device caused by normal mode noise (voltage difference between lines of the positive and negative lines) is suppressed. When another metal body that shields the electromagnetic field is provided around a housing within the chamber 10, a single housing does not have to be made of metal.

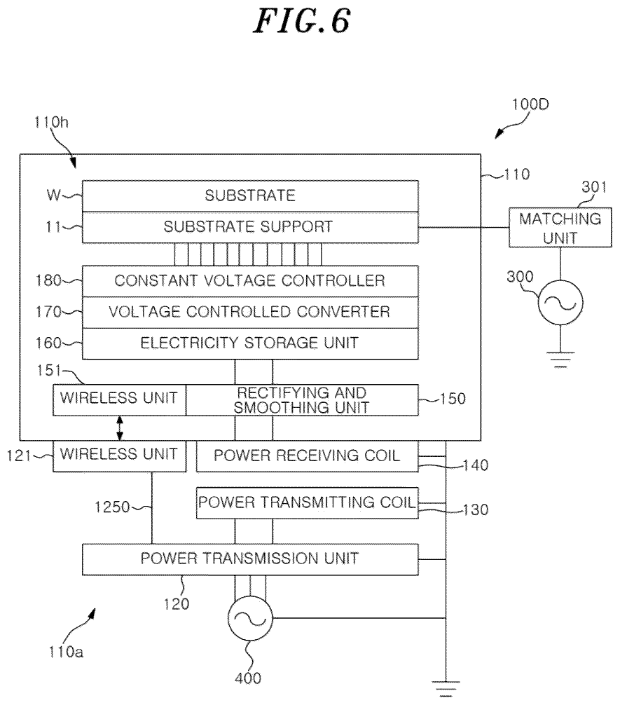

FIG. 6 is referred. FIG. 6 is a diagram schematically illustrating a plasma processing apparatus according to yet another exemplary embodiment. Hereinafter, a plasma processing apparatus 100D shown in FIG. 6 will be described from the viewpoint of its differences from the plasma processing apparatus 100C.

The plasma processing apparatus 100 D does not include the RF filter 190. In the plasma processing apparatus 100D, the rectifying and smoothing unit 150 includes a communication unit 151 which is a wireless unit. The power transmission unit 120 also includes a communication unit 121 which is a wireless unit. The aforementioned instruction signal is transmitted between the rectifying and smoothing unit 150 and the power transmission unit 120 using the communication unit 151 and the communication unit 121. The communication units 121 and 151 will be described in detail later.

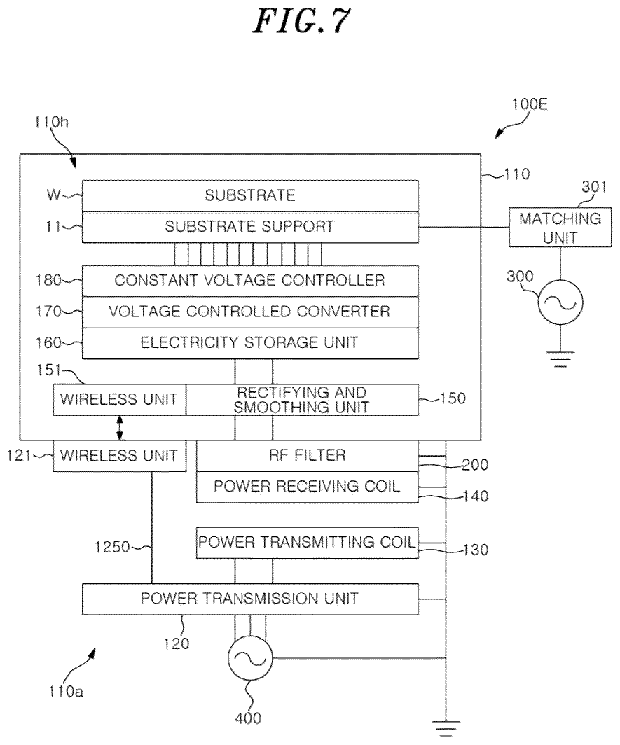

FIG. 7 is referred. FIG. 7 is a diagram schematically illustrating a plasma processing apparatus according to yet another exemplary embodiment. Hereinafter, a plasma processing apparatus 100E shown in FIG. 7 will be described from the viewpoint of its differences from the plasma processing apparatus 100D.

The plasma processing apparatus 100E further includes an RF filter 200. The RF filter 200 is connected between the power receiving coil unit 140 and the rectifying and smoothing unit 150. The RF filter 200 has the characteristic of reducing or blocking high frequency noise propagating from the power receiving coil unit 140 to the power transmitting coil 131 and the power transmission unit 120. The RF filter 200 will be described in detail later.

Hereinafter, configurations of each unit for wireless power feeding in the plasma processing apparatuses according to various exemplary embodiments will be described in detail.

### [Configuration of Power Transmission Unit]

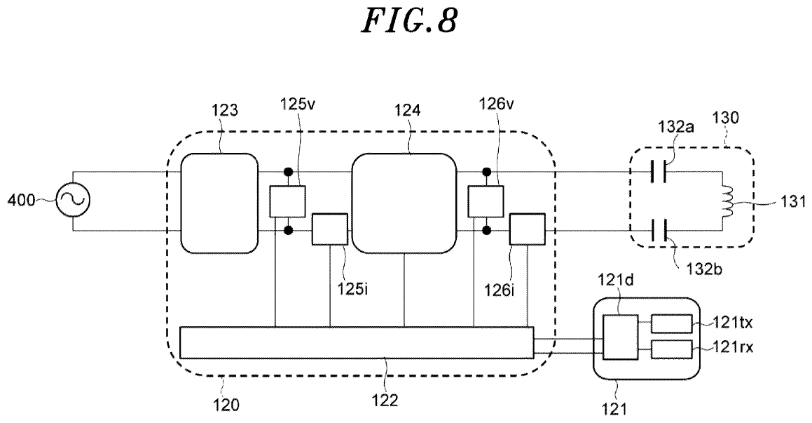

FIG. 8 is a diagram illustrating a power transmission unit according to one exemplary embodiment. As described above, the power transmission unit 120 receives the frequency of the AC power from the AC power supply 400 and converts the frequency of the AC power into a transmission frequency, thereby generating transmission AC power having the transmission frequency.

In one embodiment, the power transmission unit 120 includes a controller 122, a rectifying and smoothing unit 123, and an inverter 124. The controller 122 is configured of a processor such as a CPU or a programmable logic device such as a field-programmable gate array (FPGA).

The rectifying and smoothing unit 123 includes a rectifying circuit and a smoothing circuit (ripple filter). The rectifying circuit includes, for example, a diode bridge. The smoothing circuit includes, for example, an interline capacitor. The rectifying and smoothing unit 123 generates DC power by full-wave rectification and smoothing of the AC power from the AC power supply 400. Further, the rectifying and smoothing unit 123 may generate DC power by half-wave rectification and smoothing of the AC power from the AC power supply 400.

The inverter 124 generates transmission AC power having a transmission frequency from the DC power output by the rectifying and smoothing unit 123. The inverter 124 is, for example, a full-bridge inverter, and includes a plurality of triacs or a plurality of switching elements (for example, FETs). The inverter 124 generates the transmission AC power by ON/OFF control of the plurality of triacs or the plurality of switching elements by the controller 122. The transmission AC power output from the inverter 124 is output to the power transmitting coil unit 130.

The power transmission unit 120 may further include a voltage detector 125v, a current detector 125i, a voltage detector 126v, and a current detector 126i. The voltage detector 125v detects a voltage value between the pair of power feeding lines that connect the rectifying and smoothing unit 123 and the inverter 124 to each other. The current detector 125i detects a current value between the rectifying and smoothing unit 123 and the inverter 124. The voltage detector 126v detects a voltage value between the pair of power feeding lines that connect the inverter 124 and the power transmitting coil unit 130 to each other. The current detector 126i detects a current value between the inverter 124 and the power transmitting coil unit 130. The controller 122 is notified of the voltage value detected by the voltage detector 125v, the current value detected by the current detector 125i, the voltage value detected by the voltage detector 126v, and the current value detected by the current detector 126i.

The power transmission unit 120 includes the communication unit 121 described above. The communication unit 121 includes a driver 121d, a transmitter 121tx, and a receiver 121rx. The transmitter 121tx is a transmitter of a wireless signal or a transmitter of an optical signal. The receiver 121rx is a receiver of a wireless signal or a receiver of an optical signal. The communication unit 121 drives the transmitter 121tx using the driver 121d to output the signal from the controller 122 from the transmitter 121tx as a wireless signal or an optical signal. The signal output from the transmitter 121tx is received by the communication unit 151 (see FIG. 14) which will be described later. Furthermore, the communication unit 121 receives a signal such as the instruction signal described above from the communication unit 151 by the receiver 121rx, and inputs the received signal to the controller 122 via the driver 121d. The controller 122 switches between outputting and stopping the transmission AC power by controlling the inverter 124 in accordance with the instruction signal received from the communication unit 151 via the communication unit 121, the voltage value detected by the voltage detector 125v, the current value detected by the current detector 125i, the voltage value detected by the voltage detector 126v, and the current value detected by the current detector 126i.

### [Power Transmitting Coil Unit and Power Receiving Coil Unit]

FIGS. 9 to 11 are referred. Each of FIGS. 9 to 11 is a diagram illustrating a power transmitting coil unit and a power receiving coil unit according to one exemplary embodiment. As shown in FIG. 9, the power transmitting coil unit 130 may include, in addition to the power transmitting coil 131, a resonant capacitor 132a and a resonant capacitor 132b. The resonant capacitor 132a is connected between one of the pair of power feeding lines that connect the power transmission unit 120 and the power transmitting coil unit 130 to each other and one end of the power transmitting coil 131. The resonant capacitor 132b is connected between the other of the pair of power feeding lines and the other end of the power transmitting coil 131. The power transmitting coil 131, the resonant capacitor 132a, and the resonant capacitor 132b configure a resonant circuit for the transmission frequency. That is, the power transmitting coil 131, the resonant capacitor 132a, and the resonant capacitor 132b have a resonant frequency that is approximately equal to the transmission frequency. Further, the power transmitting coil unit 130 does not necessarily have to include either the resonant capacitor 132a or the resonant capacitor 132b.

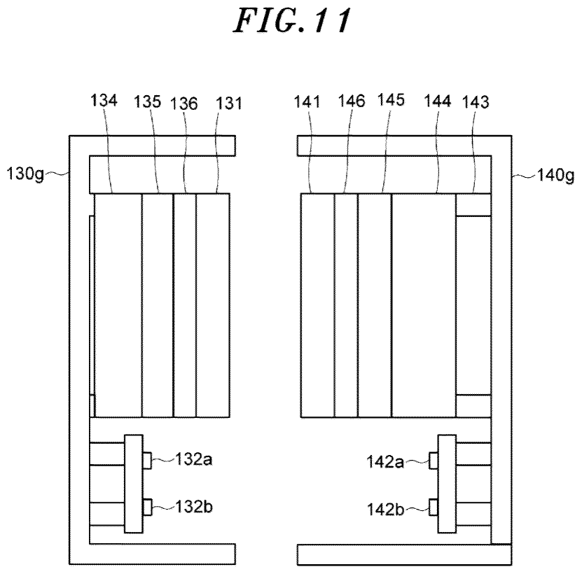

As shown in FIGS. 10 and 11, the power transmitting coil unit 130 may further include a metal housing 130g. The metal housing 130g has an open end and is grounded. The power transmitting coil 131 is disposed within the metal housing 130g with an insulation distance secured therebetween. The power transmitting coil unit 130 may further include a heat sink 134, a ferrite material 135, and a thermally conductive sheet 136. The heat sink 134 is disposed within the metal housing 130g and is supported by the metal housing 130g. The ferrite material 135 is disposed on the heat sink 134. The thermally conductive sheet 136 is disposed on the ferrite material 135. The power transmitting coil 131 is disposed on the thermally conductive sheet 136 and faces the power receiving coil 141 via the open end of the metal housing 130g. As shown in FIG. 11, the resonant capacitor 132a and the resonant capacitor 132b may be further accommodated within the metal housing 130g.

As shown in FIG. 9, the power receiving coil unit 140 includes the power receiving coil 141. The power receiving coil 141 is electromagnetically inductively coupled to the power transmitting coil 131. The power receiving coil unit 140 may include, in addition to the power receiving coil 141, a resonant capacitor 142a and a resonant capacitor 142b. The resonant capacitor 142a is connected between one of the pair of power feeding lines extending from the power receiving coil unit 140 and one end of the power receiving coil 141. The resonant capacitor 142b is connected between the other of the pair of power feeding lines and the other end of the power receiving coil 141. The power receiving coil 141, the resonant capacitor 142a, and the resonant capacitor 142b configure a resonant circuit for the transmission frequency. That is, the power receiving coil 141, the resonant capacitor 142a, and the resonant capacitor 142b have a resonant frequency that is approximately equal to the transmission frequency. Further, the power receiving coil unit 140 does not necessarily have to include either the resonant capacitor 142a or the resonant capacitor 142b.

As shown in FIGS. 10 and 11, the power receiving coil unit 140 may further include a metal housing 140g. The metal housing 140g has an open end and is grounded. The power receiving coil 141 is disposed within the metal housing 140g with an insulation distance secured therebetween. The power receiving coil unit 140 may further include a spacer 143, a heat sink 144, a ferrite material 145, and a thermally conductive sheet 146. The spacer 143 is disposed within the metal housing 140g and is supported by the metal housing 140g. The spacer 143 will be described later. The heat sink 144 is disposed on the spacer 143. The ferrite material 145 is disposed on the heat sink 144. The thermally conductive sheet 146 is disposed on the ferrite material 145. The power receiving coil 141 is disposed on the thermally conductive sheet 146 and faces the power transmitting coil 131 via the open end of the metal housing 140g. As shown in FIG. 11, the resonant capacitor 142a and the resonant capacitor 142b may be further accommodated within the metal housing 140g.

The spacer 143 is made of a dielectric material and is provided between the power receiving coil 141 and the metal housing 140g (ground). The spacer 143 provides a space stray capacitance between the power receiving coil 141 and the ground.

### [Impedance Characteristics of Power Receiving Coil Unit]

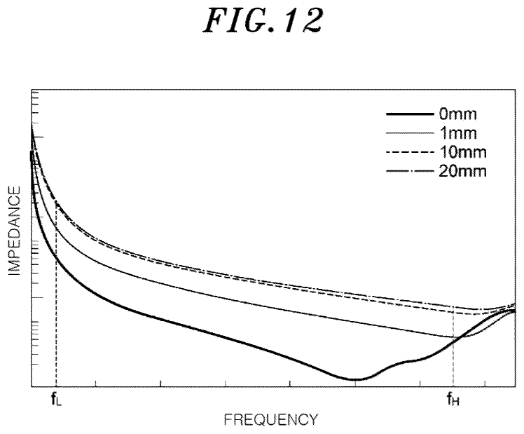

FIG. 12 is referred. FIG. 12 is a graph showing the impedance characteristics of a power receiving coil unit according to one exemplary embodiment. FIG. 12 shows the impedance characteristics of the power receiving coil unit 140 according to the thickness of the spacer 143. The thickness of the spacer 143 corresponds to the distance between the heat sink 144 and the metal housing 140g. As shown in FIG. 12, the power receiving coil unit 140 may adjust the impedance of each of frequencies f_{H} and f_{L} in accordance with the thickness of the spacer 143. Accordingly, the power receiving coil unit 140 may provide high impedance at each of the frequencies of two high frequency powers used in the plasma processing apparatus, such as the first RF signal and the second RF signal. Furthermore, since a high impedance may be obtained in the power receiving coil unit 140, the loss of high frequency power may be suppressed and a high processing rate (for example, an etching rate) may be obtained.

### [RF Filter 200]

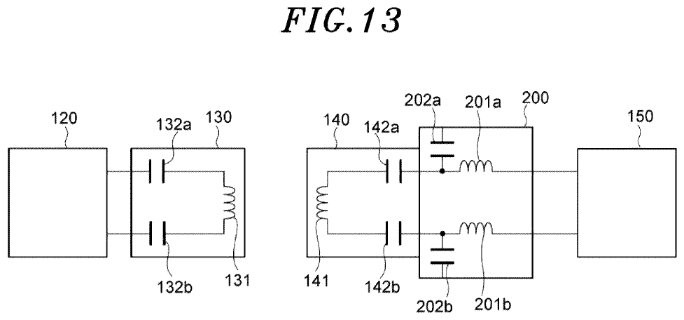

FIG. 13 is referred. FIG. 13 is a diagram illustrating an RF filter according to one exemplary embodiment. As shown in FIG. 13, the RF filter 200 is connected between the power receiving coil unit 140 and the rectifying and smoothing unit 150. The RF filter 200 includes an inductor 201a, an inductor 201b, a termination capacitor 202a, and a termination capacitor 202b. One end of the inductor 201a is connected to the resonant capacitor 142a, and the other end of the inductor 201a is connected to the rectifying and smoothing unit 150. One end of the inductor 201b is connected to the resonant capacitor 142b, and the other end of the inductor 201b is connected to the rectifying and smoothing unit 150. The termination capacitor 202a is connected between one end of the inductor 201a and the ground. The termination capacitor 202b is connected between one end of the inductor 201b and the ground. The inductor 201a and the termination capacitor 202a form a low pass filter. Additionally, the inductor 201b and the termination capacitor 202b form a low pass filter. The RF filter 200 makes it possible to obtain a high impedance at each of the frequencies of the two high frequency powers used in the plasma processing apparatus, such as the first RF signal and the second RF signal. Accordingly, the loss of high frequency power may be suppressed, and a high processing rate (for example, etching rate) may be obtained.

### [Rectifying and Smoothing Unit]

FIG. 14 is referred. FIG. 14 is a diagram illustrating a rectifying and smoothing unit according to one exemplary embodiment. In one embodiment, the rectifying and smoothing unit 150 includes a controller 152, a rectifying circuit 153, and a smoothing circuit 154. The rectifying circuit 153 is connected between the power receiving coil unit 140 and the smoothing circuit 154. The smoothing circuit 154 is connected between the rectifying circuit 153 and the electricity storage unit 160. The controller 152 is configured of a processor such as a CPU or a programmable logic device such as a field-programmable gate array (FPGA). Further, the controller 152 may be the same as or different from the controller 122.

The rectifying circuit 153 outputs power generated by full-wave rectification of the AC power from the power receiving coil unit 140. The rectifying circuit 153 is, for example, a diode bridge. Further, the rectifying circuit 153 may output power generated by half-wave rectification of the AC power from the power receiving coil unit 140.

The smoothing circuit 154 generates DC power by smoothing the power from the rectifying circuit 153. The smoothing circuit 154 may include an inductor 1541a, a capacitor 1542a, and a capacitor 1542b. One end of the inductor 1541a is connected to one of a pair of inputs of the smoothing circuit 154. The other end of the inductor 1541a is connected to a positive output (V_{OUT+}) of the rectifying and smoothing unit 150. The positive output of the rectifying and smoothing unit 150 is connected to one end of each of one or more capacitors of the electricity storage unit 160 via a positive line 160p (see FIGS. 23A and 23B) of the pair of power feeding lines described below.

One end of the capacitor 1542a is connected to one of the pair of inputs of the smoothing circuit 154 and one end of the inductor 1541a. The other end of the capacitor 1542a is connected to the other of a pair of outputs of the smoothing circuit 154 and a negative output (V_{OUT-}) of the rectifying and smoothing unit 150. The negative output of the rectifying and smoothing unit 150 is connected to the other end of each of one or more capacitors of the electricity storage unit 160 via a negative line 160m (see FIGS. 23A and 23B) of the pair of power feeding lines described below. One end of the capacitor 1542b is connected to the other end of the inductor 1541a. The other end of the capacitor 1542b is connected to the other of the pair of outputs of the smoothing circuit 154 and the negative output (V_{OUT-}) of the rectifying and smoothing unit 150.

The rectifying and smoothing unit 150 may further include a voltage detector 155v and a current detector 155i. The voltage detector 155v detects a voltage value between the positive output and the negative output of the rectifying and smoothing unit 150. The current detector 155i detects a current value between the rectifying and smoothing unit 150 and the electricity storage unit 160. The voltage value detected by the voltage detector 155v and the current value detected by the current detector 155i are notified to the controller 152. The controller 152 generates the instruction signal described above in accordance with the power stored in the electricity storage unit 160. For example, when the power stored in the electricity storage unit 160 is equal to or less than a first threshold value, the controller 152 generates an instruction signal to instruct the power transmission unit 120 to feed power, that is, to output transmission AC power. The first threshold value is the power consumption at a load, for example, the power consuming member 240. In addition, considering margin, the power consumption of a load such as the power consuming member 240 may be multiplied by a certain value (for example, a value within the range of 1 to 3). When the power stored in the electricity storage unit 160 is greater than a second threshold value, the controller 152 generates an instruction signal to instruct the power transmission unit 120 to stop feeding power, that is, to stop outputting the transmission AC power. The second threshold value is a value that does not exceed limit electricity storage power of the electricity storage unit 160. The second threshold value is, for example, a value obtained by multiplying the limit electricity storage power of the electricity storage unit 160 by a certain value (for example, a value equal to or less than 1).

The rectifying and smoothing unit 150 includes the communication unit 151 described above. The communication unit 151 includes a driver 151d, a transmitter 151tx, and a receiver 151rx. The transmitter 151tx is a transmitter of a wireless signal or a transmitter of an optical signal. The receiver 151rx is a receiver of a wireless signal or a receiver of an optical signal. The communication unit 151 drives the transmitter 151tx by the driver 151d to output a signal from the controller 122, such as an instruction signal, from the transmitter 151tx as a wireless signal or an optical signal. The signal output from the transmitter 151tx is received by the communication unit 121 of the power transmission unit 120. Furthermore, the communication unit 151 receives a signal from the communication unit 121 by the receiver 151rx, and inputs the received signal to the controller 152 via the driver 151d.

### [RF Filter 190]

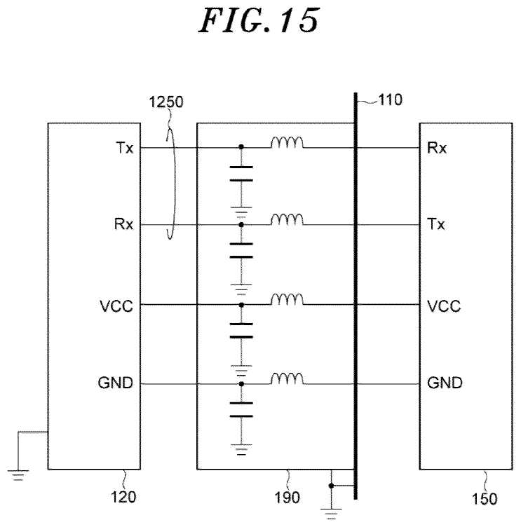

FIG. 15 is referred. FIG. 15 is a diagram illustrating the RF filter 190 according to one exemplary embodiment. As shown in FIG. 15, the signal line 1250 may include a first signal line electrically connecting a signal output (Tx) of the power transmission unit 120 and a signal input (Rx) of the rectifying and smoothing unit 150, and a second signal line electrically connecting the signal input (Rx) of the power transmission unit 120 and the signal output (Tx) of the rectifying and smoothing unit 150. The signal line 1250 may include a signal line connecting a first reference voltage terminal (VCC) of the power transmission unit 120 and the first reference voltage terminal (VCC) of the rectifying and smoothing unit 150, and a signal line connecting a second reference voltage terminal (GND) of the power transmission unit 120 and the second reference voltage terminal (GND) of the rectifying and smoothing unit 150. The signal line 1250 may be a shielded cable covered with a shield at ground potential. In this connection, a plurality of signal lines constituting the signal line 1250 may be individually covered with a shield or may be collectively covered with a shield. The RF filter 190 provides a low pass filter for each of the plurality of signal lines constituting the signal line 1250. The low pass filter may be an LC filter including an inductor and a capacitor. The inductor of the low pass filter forms a portion of the corresponding signal line. The capacitor is connected between one end of the inductor connected to the power transmission unit 120 and the ground. The RF filter 190 makes it possible to suppress the propagation of high frequency power (high frequency noise) via the signal line 1250 between the rectifying and smoothing unit 150 and the power transmission unit 120.

### [Communication Unit of Power Transmission Unit and Communication Unit of Rectifying and Smoothing Unit]

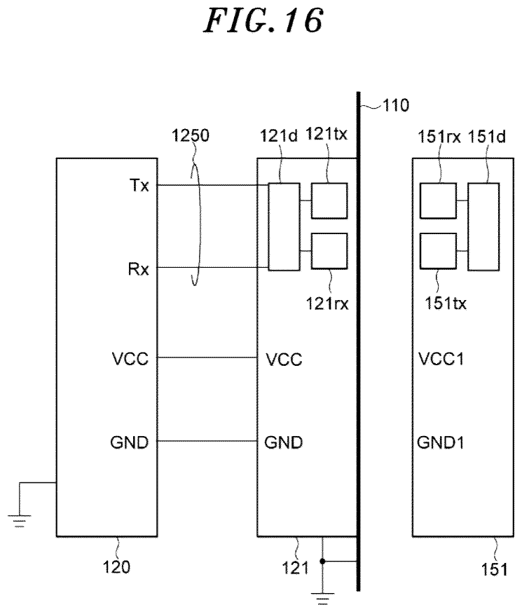

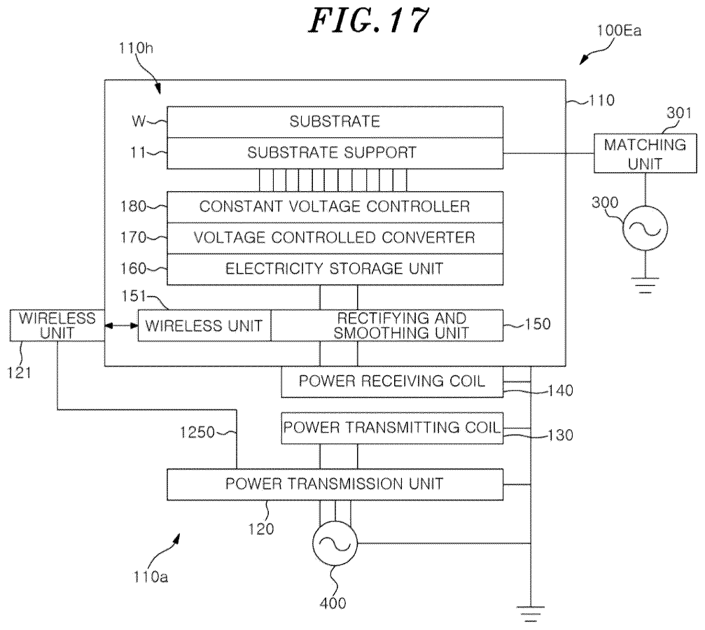

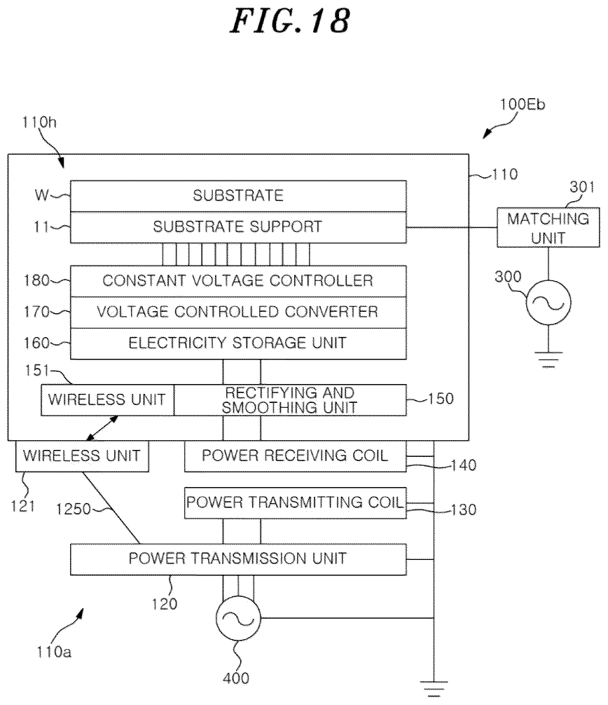

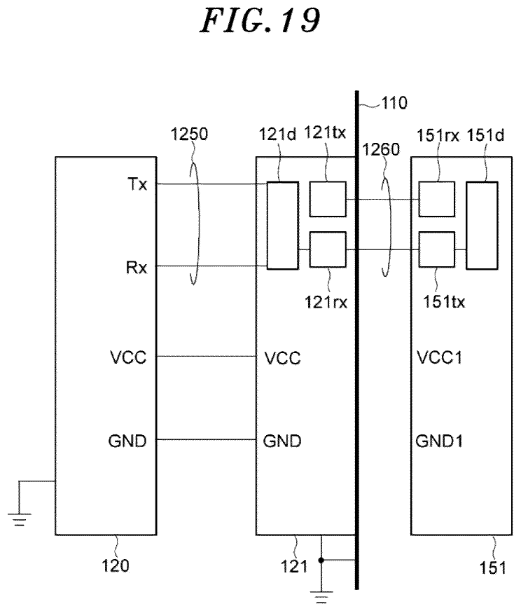

FIGS. 16 to 18 are referred. FIG. 16 is a diagram illustrating a communication unit of a power transmission unit and a communication unit of a rectifying and smoothing unit according to one exemplary embodiment. Each of FIGS. 17 and 18 is a diagram schematically illustrating a plasma processing apparatus according to yet another exemplary embodiment. As shown in FIGS. 6, 7, 16, 17, and 18, the communication unit 121 and the communication unit 151 may be configured to transmit signals such as the instruction signal described above between each other via wireless communication. The communication via wireless communication may be performed by optical communication. When the communication unit 121 and the communication unit 151 transmit signals therebetween via wireless communication, the communication unit 121 and the communication unit 151 may be disposed in any location as long as there is no shielding material interposed therebetween. According to the examples shown in these drawings, the RF filter 190 is not required. Further, in various exemplary embodiments including the examples shown in FIGS. 16 to 18, the signal line 1250 may be a shielded cable covered with a shield at ground potential. In this connection, the plurality of signal lines constituting the signal line 1250 may be individually covered with a shield or may be collectively covered with a shield.

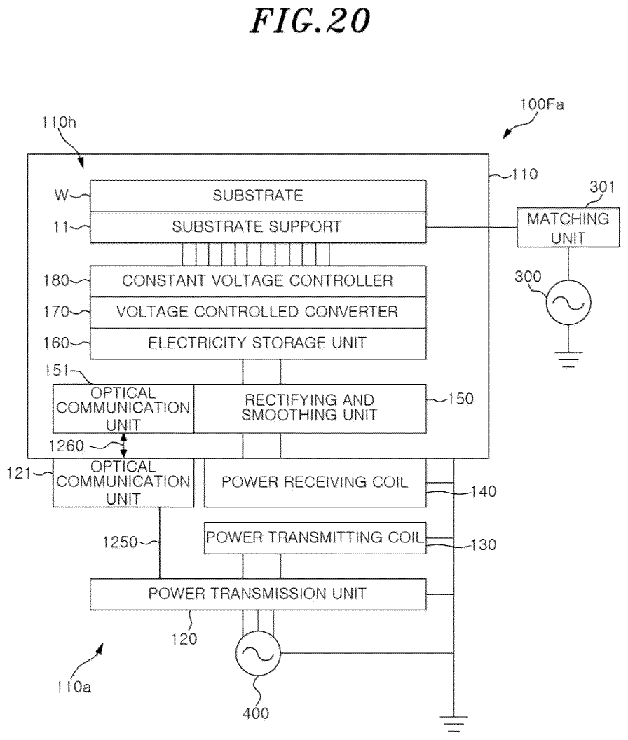

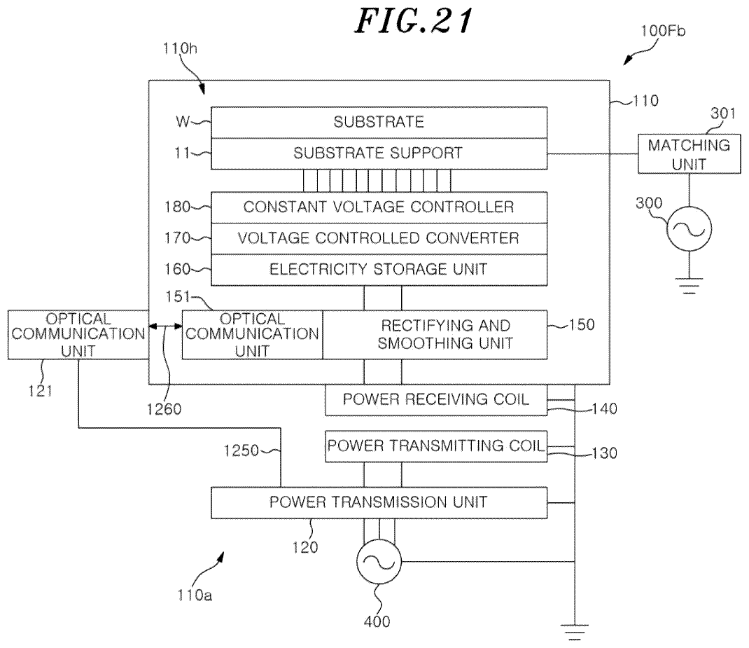

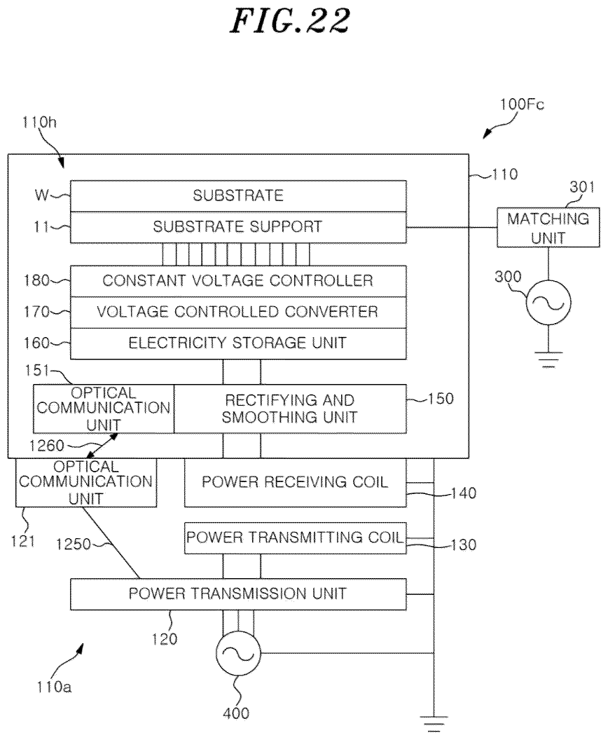

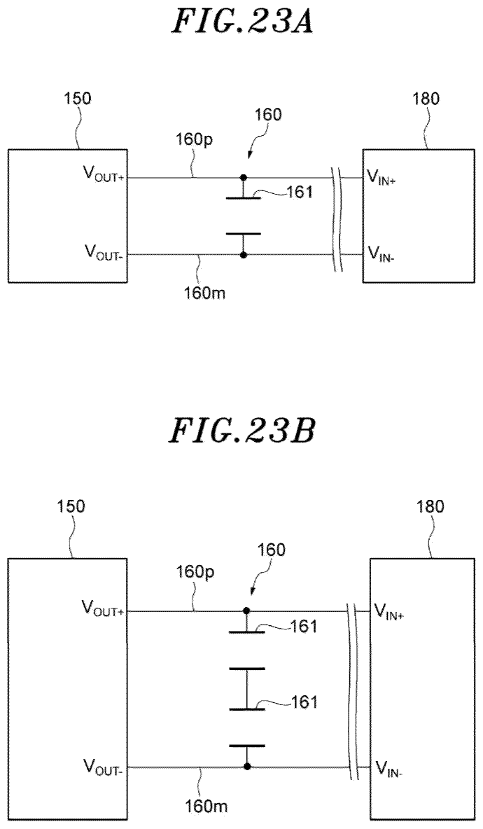

FIGS. 19 to 22 are referred. FIG. 19 is a diagram illustrating a communication unit of a power transmission unit and a communication unit of a rectifying and smoothing unit according to another exemplary embodiment. Each of FIGS. 20 to 22 is a diagram schematically illustrating a plasma processing apparatus according to yet another exemplary embodiment. As shown in FIGS. 19 to 22, the communication unit 121 and the communication unit 151 may be configured to transmit signals (optical signals) such as the above-mentioned instruction signal between each other via an optical fiber 1260, that is, by optical fiber communication. When the communication unit 121 and communication unit 151 transmit signals therebetween via the optical fiber 1260, the communication unit 121 and the communication unit 151 may be disposed in any location as long as the bending radius of the optical fiber 1260 falls within the allowable range. Also in the examples shown in these drawings, the RF filter 190 becomes unnecessary.

### [Electricity Storage Unit]

FIGS. 23A and 23B are referred. Each of FIGS. 23A and 23B is a diagram illustrating an electricity storage unit according to one exemplary embodiment. As shown in FIG. 23A, the electricity storage unit 160 includes a capacitor 161. The capacitor 161 is connected between the pair of power feeding lines, that is, the positive line 160p and the negative line 160m. The positive line 160p extends from the positive output (V_{OUT+}) of the rectifying and smoothing unit 150 toward a load. The negative line 160m extends from the negative output (V_{OUT-}) of the rectifying and smoothing unit 150 toward the load. The capacitor 161 may be a polarized capacitor. The capacitor 161 may be an electric double layer or lithium ion battery.

As shown in FIG. 23B, the electricity storage unit 160 may include a plurality of capacitors 161. The plurality of capacitors 161 are connected in series between the positive line 160p and the negative line 160m. The plurality of capacitors 161 may have the same capacitance or may have different capacitances. Each of the plurality of capacitors 161 may be a polarized capacitor. Each of the plurality of capacitors 161 may be an electric double layer or a lithium ion battery. The electricity storage unit 160 needs to be used under conditions in which a total value of the input voltage thereto and the line-to-line potential difference due to normal mode noise is lower than the allowable input voltage. When the electricity storage unit 160 includes the plurality of capacitors 161 connected in series, the allowable input voltage of the electricity storage unit 160 becomes high. Accordingly, according to the example shown in FIG. 23B, the noise resistance of the electricity storage unit 160 is improved.

### [Voltage Controlled Converter]

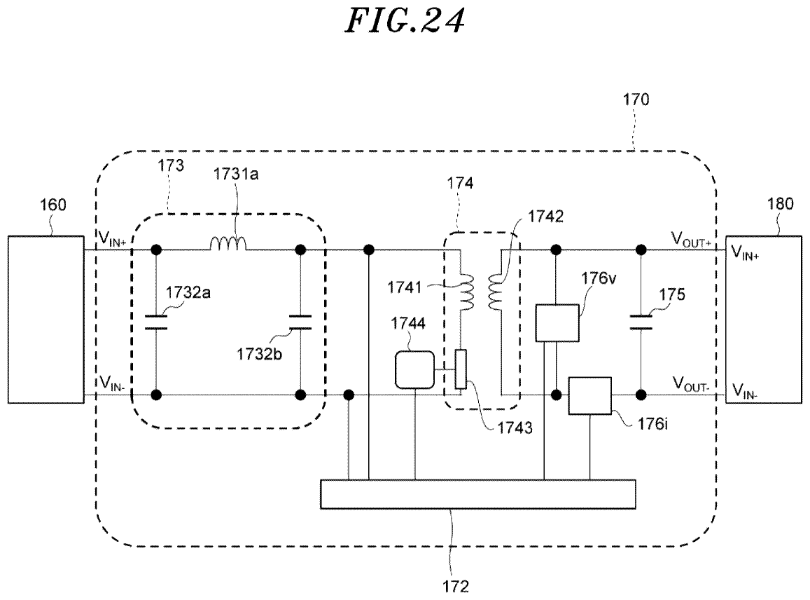

FIG. 24 is referred. FIG. 24 is a diagram illustrating a voltage control converter according to one exemplary embodiment. The voltage controlled converter 170 is a DC-DC converter. The voltage controlled converter 170 is connected between the electricity storage unit 160 and the constant voltage controller 180. The positive line 160p is connected to a positive input (V_{IN+}) of the voltage controlled converter 170. The negative line 160m is connected to a negative input (V_{IN-}) of the voltage controlled converter 170. The positive output (V_{OUT+}) of the voltage controlled converter 170 is connected to the positive input (V_{IN+}) of the constant voltage controller 180. The negative output (V_{OUT-}) of the voltage controlled converter 170 is connected to the negative input (V_{IN-}) of the constant voltage controller 180.

The voltage controlled converter 170 may include a controller 172, a low-pass filter 173, a transformer 174, and a capacitor 175. The low-pass filter 173 may include an inductor 1731a, a capacitor 1732a, and a capacitor 1732b. One end of the inductor 1731a is connected to the positive input (V_{IN+}) of the voltage controlled converter 170. The other end of the inductor 1731a is connected to one end of a primary coil of the transformer 174. One end of the capacitor 1732a is connected to one end of the inductor 1731a and the positive input (V_{IN+}) of the voltage controlled converter 170. The other end of the capacitor 1732a is connected to the negative input (V_{IN-}) of the voltage controlled converter 170. One end of the capacitor 1732b is connected to the other end of the inductor 1731a. The other end of the capacitor 1732b is connected to the negative input (V_{IN-}) of the voltage controlled converter 170.

The transformer 174 includes a primary coil 1741, a secondary coil 1742, and a switch 1743. The other end of the primary coil 1741 is connected to the negative input (V_{IN-}) of the voltage controlled converter 170 via the switch 1743. One end of the secondary coil 1742 is connected to one end of the capacitor 175 and the positive output (V_{OUT+}) of the voltage controlled converter 170. The other end of the secondary coil 1742 is connected to the other end of the capacitor 175 and the negative output (V_{OUT-}) of the voltage controlled converter 170.

A driver 1744 is connected to the switch 1743. The driver 1744 opens and closes the switch 1743. When the switch 1743 is closed, that is, when the other end of the primary coil 1741 and the negative input (V_{IN-}) are in a conductive state, the other end of the primary coil 1741 is connected to the negative input (V_{IN-}) of the voltage controlled converter 170, and DC power from the voltage controlled converter 170 is provided to the constant voltage controller 180. When the switch 1743 is open, that is, when the other end of the primary coil 1741 and the negative input (V_{IN-}) are in a non-conductive state, the connection between the other end of the primary coil 1741 and the negative input (V_{IN-}) of the voltage controlled converter 170 is cut off, and the supply of DC power from the voltage controlled converter 170 to the constant voltage controller 180 is shut off.

The voltage controlled converter 170 may further include a voltage detector 176v and a current detector 176i. The voltage detector 176v detects a voltage value between both ends of the secondary coil 1742 or the voltage value between the positive output and the negative output of the voltage controlled converter 170. The current detector 176i measures a current value between the other end of the secondary coil 1742 and the negative output of the voltage controlled converter 170. The voltage value detected by the voltage detector 176v and the current value detected by the current detector 176i are notified to the controller 172. The controller 172 may be the same as or different from at least one of the controller 122 or the controller 152.

When the voltage value detected by the voltage detector 176v is equal to or higher than the threshold value, the controller 172 controls the driver 1744 to shut off the supply of DC power from the voltage controlled converter 170 to the constant voltage controller 180. The voltage value between the positive output and the negative output of the voltage controlled converter 170 is an added value of the output voltage value of the voltage controlled converter 170 and the line-to-line potential difference due to normal mode noise. In this embodiment, damage to the load of the voltage controlled converter 170 due to an overvoltage caused by the line-to-line potential difference due to normal mode noise may be suppressed.

### [Constant Voltage Controller]

FIGS. 25 and 26 are referred. FIGS. 25 and 26 are diagrams illustrating a constant voltage controller according to some exemplary embodiments. The constant voltage controller 180 is connected between the electricity storage unit 160 and at least one power consuming member 240, and is configured to control the application of voltage (application of DC voltage) to at least one power consuming member 240 and the stopping of the application.

The constant voltage controller 180 includes a controller 182 and at least one switch 183. The positive input (V_{IN+}) of the constant voltage controller 180 is connected to the power consuming member 240 via the switch 183. The negative input (V_{IN-}) of the constant voltage controller 180 is connected to the power consuming member 240. The switch 183 is controlled by the controller 182. When the switch 183 is closed, the DC voltage from the constant voltage controller 180 is applied to the power consuming member 240. When the switch 183 is open, the application of DC voltage from the constant voltage controller 180 to the power consuming member 240 is stopped. Further, the controller 182 may be the same as or different from at least one of the controller 122, the controller 152, or the controller 172.

In the embodiment shown in FIGS. 25 and 26, the plasma processing apparatus includes a plurality of power consuming members 240. The constant voltage controller 180 includes the controller 182 and a plurality of switches 183. The positive input (V_{IN+}) of the constant voltage controller 180 is connected to the plurality of power consuming members 240 via the plurality of switches 183. The negative input (V_{IN-}) of the constant voltage controller 180 is connected to the plurality of power consuming members 240.

In the embodiment shown in FIGS. 25 and 26, the plurality of power consuming members 240 may include a plurality of heaters (resistive heating elements). The plurality of heaters may be provided within the substrate support 11. In the embodiment shown in FIG. 25, a plurality of resistors 260 are disposed adjacent to each of the plurality of heaters. Each of the plurality of resistors 260 has a resistance value that changes with temperature. Each of the plurality of resistors 260 is, for example, a thermistor. Each of the plurality of resistors 260 is connected in series with a reference resistor (not shown). The constant voltage controller 180 includes a plurality of measuring units 184. Each of the plurality of measuring units 184 applies a reference voltage to a series connection of a corresponding resistor among the plurality of resistors 260 and the reference resistor, and detects the voltage value between both ends of the resistor. Each of the plurality of measuring units 184 notifies the controller 182 of the detected voltage value. The controller 182 specifies the temperature of an area in which the corresponding heater among the plurality of heaters is disposed from the notified voltage value, and controls the application of DC voltage to the corresponding heater so as to bring the temperature of the area closer to the target temperature. Further, instead of the plurality of resistors 260, an optical fiber thermometer may be disposed. In this connection, wiring between the plurality of resistors 260 and the plurality of measuring units 184 is not required, so the influence of high frequency conductive noise on the power consuming member 240 may be eliminated.

In the embodiment shown in FIG. 26, the constant voltage controller 180 includes a voltage detector 185v and a plurality of current detectors 185i. The voltage detector 185v detects the voltage value applied to each of the plurality of heaters. The plurality of current detectors 185i measure the value of the current supplied to the corresponding one of the plurality of heaters, that is, the current value. The plurality of measuring units 184 specifies the resistance value of the corresponding one of the plurality of heaters from the current value detected by the corresponding one of the plurality of current detectors 185i and the voltage value detected by the voltage detector 185v. The controller 182 specifies the temperature of each of a plurality of areas in which each of the plurality of heaters are disposed, based on the detected resistance value of each of the plurality of heaters. The controller 182 controls the application of DC voltage to each of the plurality of heaters so that the temperature of each of the plurality of areas approaches the target temperature.

[Exemplary embodiment Regarding Integration of Rectifying and Smoothing Unit and Electricity Storage Unit]

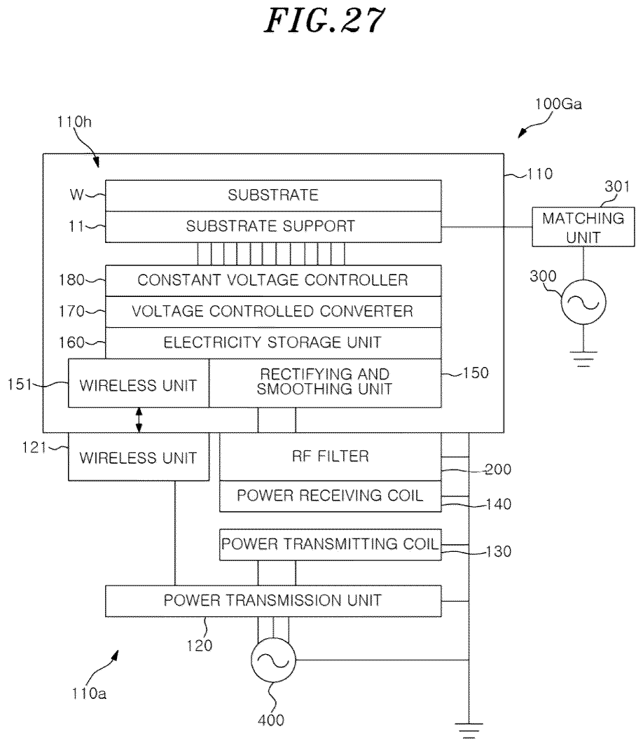

FIGS. 27 to 29 are referred. Each of FIGS. 27 to 29 is a diagram schematically illustrating a plasma processing apparatus according to yet another exemplary embodiment. Hereinafter, each of plasma processing apparatuses 100Ga, 100Gb, and 100Gc shown in each of FIGS. 27 to 29 will be described in terms of their differences from the plasma processing apparatus 100E (see FIG. 7).

In each of the plasma processing apparatuses 100Ga, 100Gb, and 100Gc, the rectifying and smoothing unit 150 and the electricity storage unit 160 are integrated with each other. That is, in each of the plasma processing apparatuses 100Ga, 100Gb, and 100Gc, the rectifying and smoothing unit 150 and the electricity storage unit 160 are both disposed within a single metal housing or formed on a single circuit board. In each of the plasma processing apparatuses 100Ga, 100Gb, and 100Gc, an insulation distance may be ensured between each of the rectifying and smoothing unit 150 and the electricity storage unit 160 and the ground frame 110. In each of the plasma processing apparatuses 100Ga, 100Gb, and 100Gc, the power transmitting coil unit 130 (or the power transmitting coil 131) and the power receiving coil unit 140 (or the power receiving coil 141) may be disposed within a single grounded metal housing.

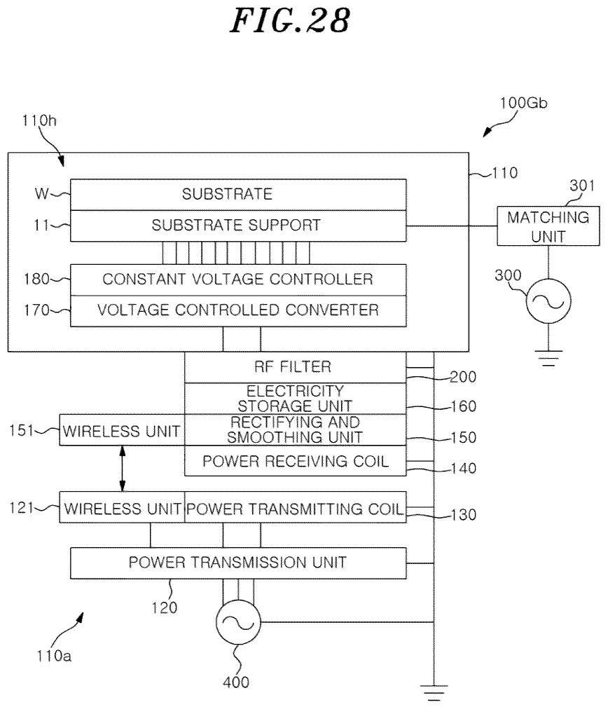

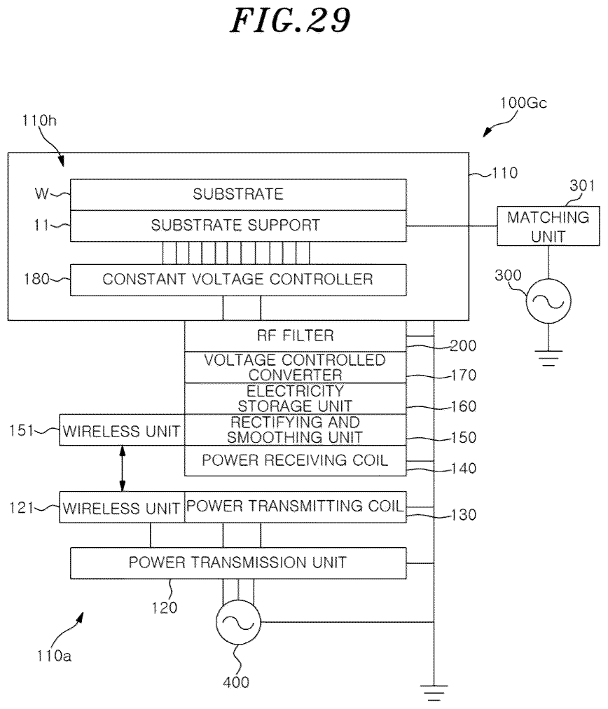

As shown in FIG. 27, the rectifying and smoothing unit 150 and the electricity storage unit 160 may both be disposed within the space 110h. As shown in FIG. 28, the rectifying and smoothing unit 150 and electricity storage unit 160 may both be disposed in the space 110a. As shown in FIG. 28, the RF filter 200 may be connected between the electricity storage unit 160 and the voltage controlled converter 170 disposed within the space 110h. As shown in FIG. 29, the rectifying and smoothing unit 150, the electricity storage unit 160, and the voltage controlled converter 170 may all be disposed in the space 110a. Furthermore, the RF filter 200 may be connected between the electricity storage unit 160 and the constant voltage controller 180 disposed within the space 110h. The RF filter 200 reduces high frequency conductive noise (common mode noise) and ensures a withstand voltage margin for the electricity storage unit 160. Furthermore, the RF filter 200 may suppress the loss of high frequency power and achieve a high processing rate (for example, etching rate).

In addition, in each of the plasma processing apparatuses 100Gb and 100Gc, when an insulation distance is secured between each of the rectifying and smoothing unit 150 and the electricity storage unit 160 and the ground frame 110, the RF filter 200 does not need to be provided.

### [Exemplary Embodiment Regarding Disposition of Rectifying and Smoothing Unit]

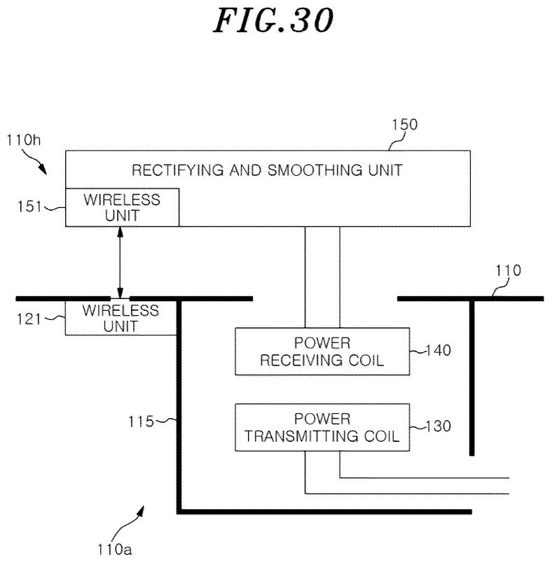

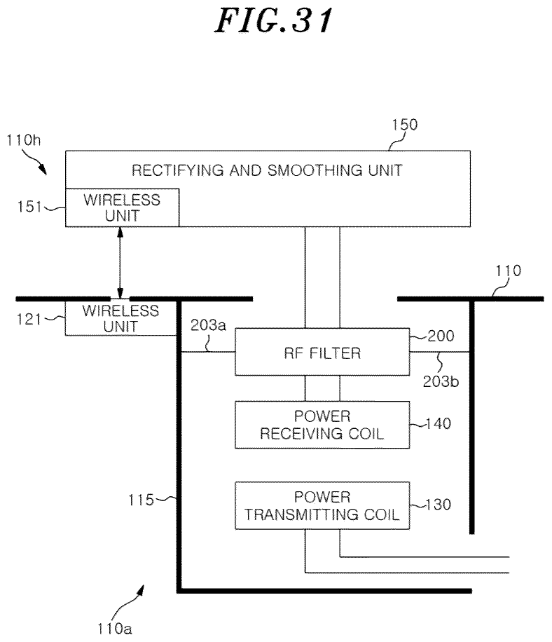

FIGS. 30 and 31 are referred. FIG. 30 is a diagram illustrating the disposition of a rectifying and smoothing unit according to one exemplary embodiment. FIG. 31 is a diagram illustrating the disposition of a rectifying and smoothing unit according to another exemplary embodiment. As shown in FIGS. 30 and 31, the rectifying and smoothing unit 150 may be disposed within the space 110h. The power transmitting coil unit 130 and the power receiving coil unit 140 may be disposed within a metal housing 115 in the space 110a. The metal housing 115 is grounded together with the ground frame 110. As shown in FIG. 31, the RF filter 200 may be connected between the power receiving coil unit 140 and the rectifying and smoothing unit 150, and may be disposed within the metal housing 115. In this connection, as shown in FIG. 31, the termination capacitor 202a (see FIG. 13) of the RF filter 200 is connected to the metal housing 115, which is the ground, via a wiring 203a. The termination capacitor 202b (see FIG. 13) is connected to the metal housing 115, which is the ground, via a wiring 203b.

In each of the embodiments shown in FIGS. 30 and 31, an insulating distance may be ensured between the rectifying and smoothing unit 150 and the ground frame 110. Furthermore, an insulation distance may be ensured between each of the power feeding lines connecting the rectifying and smoothing unit 150 and the power receiving coil unit 140 and each of the ground frame 110 and the metal housing 115. Furthermore, an insulation distance may be ensured between the RF filter 200 and each of the ground frame 110 and the metal housing 115. Furthermore, an insulation distance may be ensured between the power receiving coil unit 140 and each of the ground frame 110 and the metal housing 115. Furthermore, an insulation distance may be ensured between the power transmitting coil unit 130 and each of the ground frame 110 and the metal housing 115.

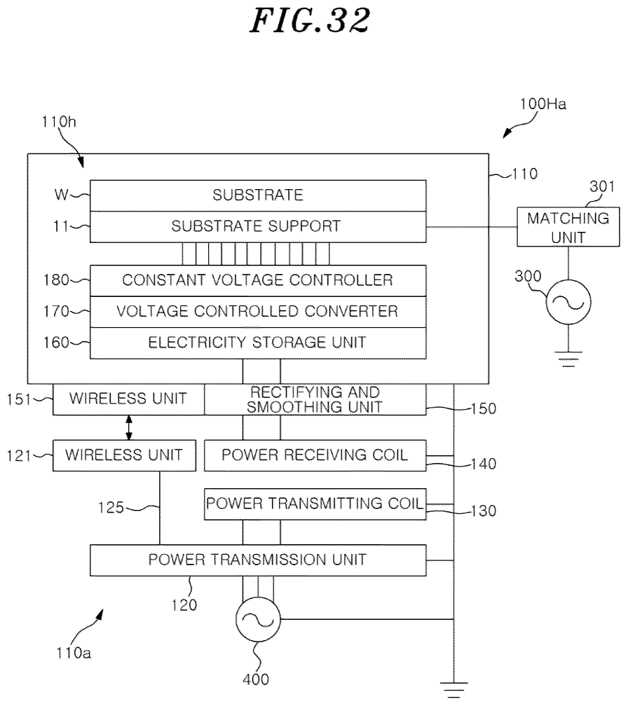

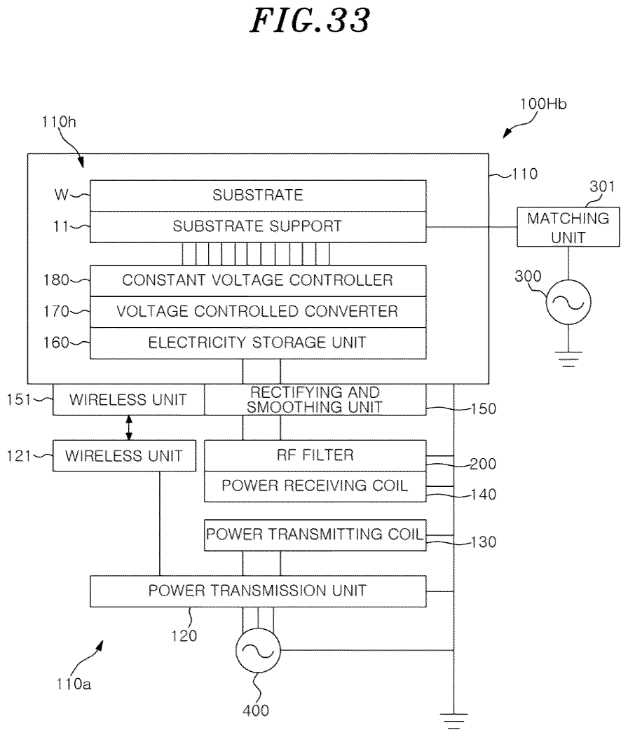

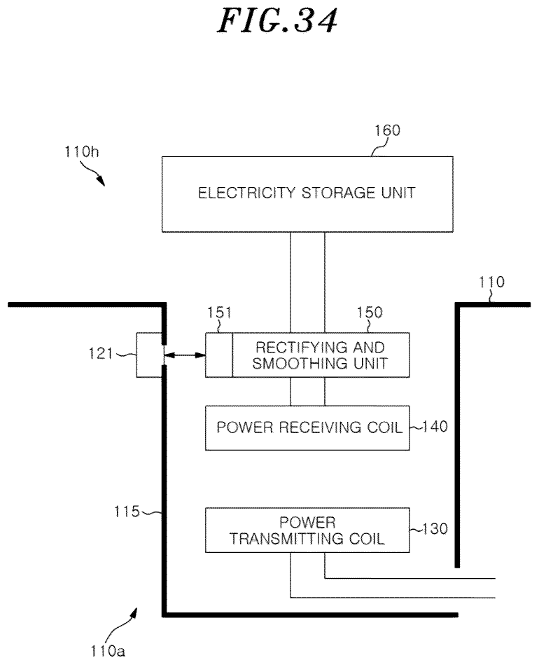

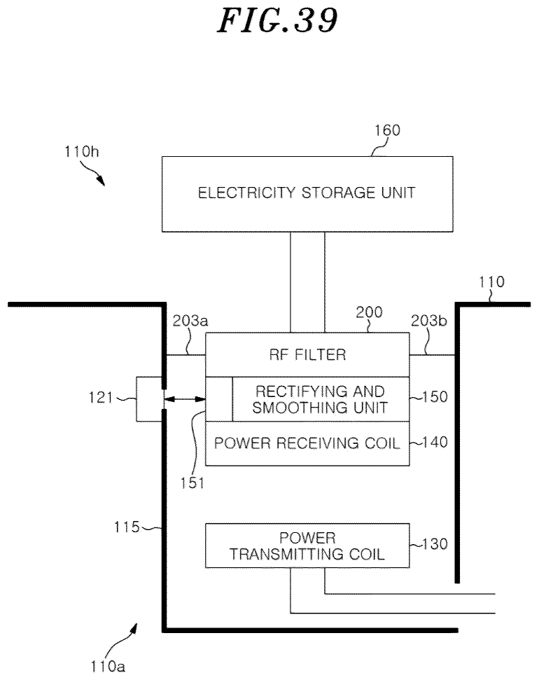

FIGS. 32 and 39 are referred. Each of FIGS. 32 and 33 is a diagram schematically illustrating a plasma processing apparatus according to yet another exemplary embodiment. Each of FIGS. 34 to 39 is a diagram illustrating the disposition of a rectifying and smoothing unit according to yet another exemplary embodiment. Hereinafter, each of plasma processing apparatuses 100Ha and 100Hb shown in each of FIGS. 32 and 33 will be described in terms of their differences from the plasma processing apparatus 100E (see FIG. 7).

As shown in FIGS. 32 and 33, in each of the plasma processing apparatuses 100Ha and 100Hb, the rectifying and smoothing unit 150 is disposed in the space 110a. This increases the degree of freedom in the layout of other components within the space 110h.

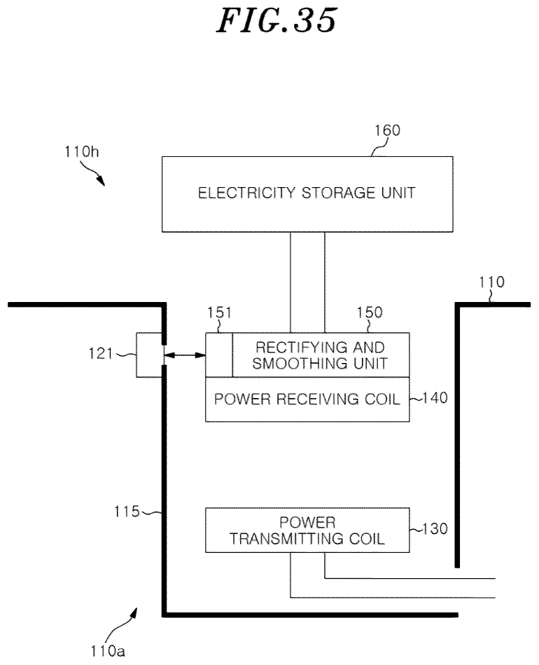

As shown in FIGS. 32, 34, and 35, in the plasma processing apparatus 100Ha, the rectifying and smoothing unit 150 is connected to the electricity storage unit 160 provided in the space 110h without passing through the RF filter 200. Furthermore, in the plasma processing apparatus 100Ha, the rectifying and smoothing unit 150 is connected to the power receiving coil unit 140 without passing through the RF filter 200. In the space 110a, the power transmitting coil unit 130, the power receiving coil unit 140, and the rectifying and smoothing unit 150 may be disposed within the metal housing 115 that is grounded together with the ground frame 110. Moreover, both the power transmitting coil unit 130 and the power receiving coil unit 140 may be disposed within a single metal housing. As shown in FIG. 34, the rectifying and smoothing unit 150 may be located away from the power receiving coil unit 140. Alternatively, as shown in FIG. 35, the rectifying and smoothing unit 150 may be integrated with the power receiving coil unit 140. That is, the rectifying and smoothing unit 150 and the power receiving coil unit 140 may both be disposed within a single metal housing, or may be provided on a single circuit board.

As shown in FIGS. 34 and 35, in the plasma processing apparatus 100Ha, the power transmitting coil unit 130, the power receiving coil unit 140, the rectifying and smoothing unit 150, the electricity storage unit 160, the pair of power feeding lines connecting the power receiving coil unit 140 and the rectifying and smoothing unit 150, and the pair of power feeding lines connecting the rectifying and smoothing unit 150 and the electricity storage unit 160 may each have an insulation distance with respect to the ground frame 110 and the metal housing 115. This may reduce common mode noise. Furthermore, a high impedance to high frequency power may be obtained in the rectifying and smoothing unit 150 and/or the power receiving coil unit 140. Accordingly, the loss of high frequency power may be suppressed, and a high processing rate (for example, etching rate) may be obtained.

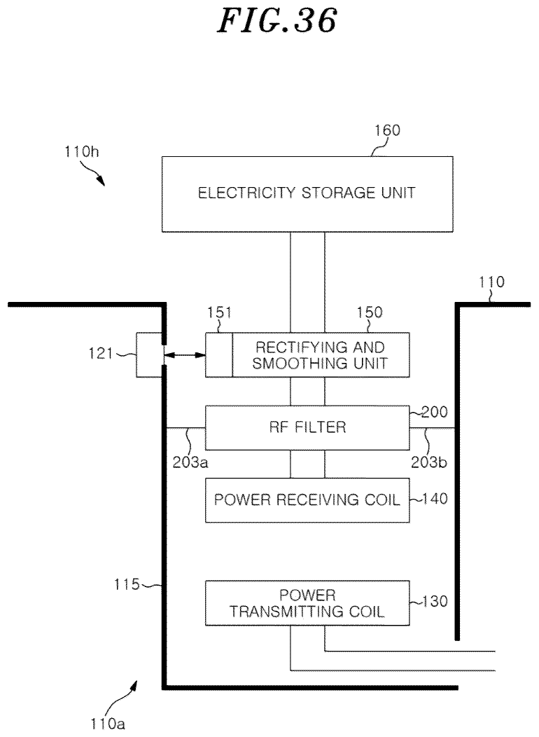

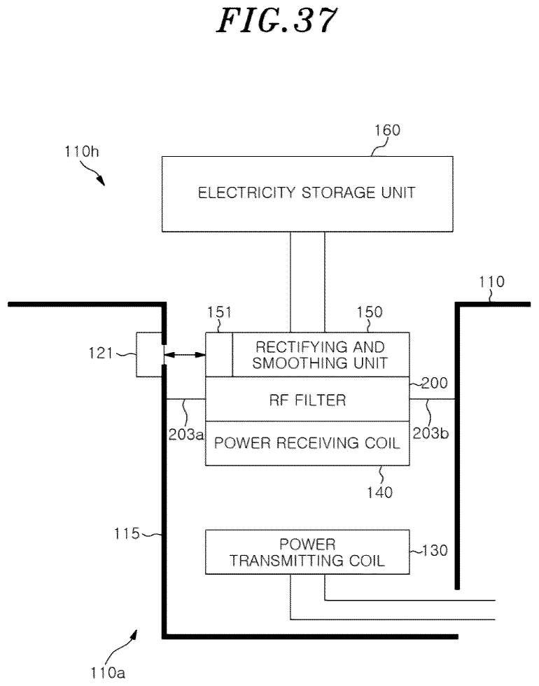

As shown in FIGS. 33, 36, and 37, in the plasma processing apparatus 100Hb, the rectifying and smoothing unit 150 is connected to the electricity storage unit 160 provided in the space 110h without passing through the RF filter 200. Further, in the plasma processing apparatus 100Hb, the rectifying and smoothing unit 150 is connected to the power receiving coil unit 140 via the RF filter 200. In the space 110a, the power transmitting coil unit 130, the power receiving coil unit 140, the RF filter 200, and the rectifying and smoothing unit 150 may be disposed within the metal housing 115 that is grounded together with the ground frame 110. In this connection, as shown in FIGS. 36 and 37, the termination capacitor 202a (see FIG. 13) of the RF filter 200 is connected to the metal housing 115, which is the ground, via the wiring 203a. The termination capacitor 202b (see FIG. 13) is connected to the metal housing 115, which is the ground, via the wiring 203b. Moreover, both the power transmitting coil unit 130 and the power receiving coil unit 140 may be disposed within a single metal housing. As shown in FIG. 36, the rectifying and smoothing unit 150 may be located away from the power receiving coil unit 140 and the RF filter 200. Alternatively, as shown in FIG. 37, the rectifying and smoothing unit 150 may be integrated with the RF filter 200 and the power receiving coil unit 140. That is, the rectifying and smoothing unit 150, the RF filter 200, and the power receiving coil unit 140 may all be disposed within a single metal housing, or may be provided on a single circuit board.

As shown in FIGS. 36 and 37, in the plasma processing apparatus 100Hb, the power transmitting coil unit 130, the power receiving coil unit 140, the RF filter 200, the rectifying and smoothing unit 150, the electricity storage unit 160, the pair of power feeding lines connecting the power receiving coil unit 140 and the RF filter 200, the pair of power feeding lines connecting the RF filter 200 and the rectifying and smoothing unit 150, and the pair of power feeding lines connecting the rectifying and smoothing unit 150 and the electricity storage unit 160 may each have an insulation distance with respect to the ground frame 110 and the metal housing 115. This may reduce common mode noise. Moreover, the RF filter 200 may provide a high impedance to high frequency power. Accordingly, the loss of high frequency power may be suppressed, and a high processing rate (for example, etching rate) may be obtained.

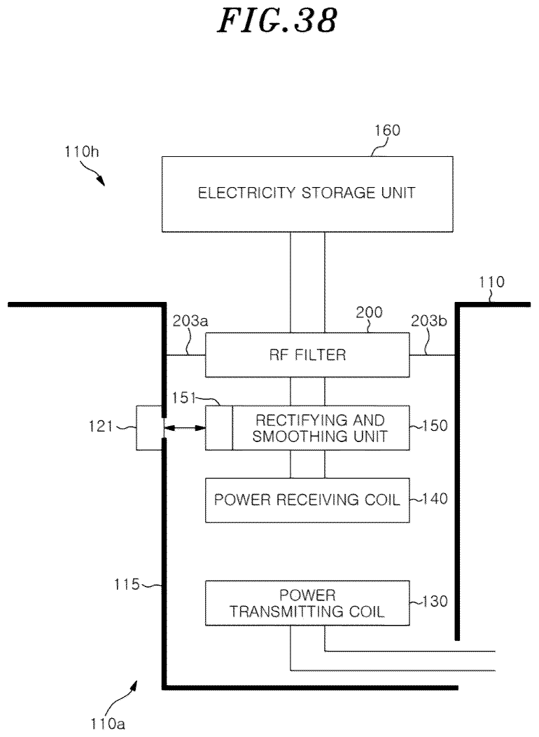

As shown in FIGS. 38 and 39, the RF filter 200 may be connected between the rectifying and smoothing unit 150 and the electricity storage unit 160 provided in the space 110h. The power transmitting coil unit 130, the power receiving coil unit 140, the rectifying and smoothing unit 150, and the RF filter 200 may be disposed within the metal housing 115 that is grounded together with the ground frame 110 in the space 110a. In this connection, as shown in FIGS. 38 and 39, the termination capacitor 202a (see FIG. 13) of the RF filter 200 is connected to the metal housing 115, which is the ground, via the wiring 203a. The termination capacitor 202b (see FIG. 13) is connected to the metal housing 115, which is the ground, via the wiring 203b. Moreover, both the power transmitting coil unit 130 and the power receiving coil unit 140 may be disposed within a single metal housing. As shown in FIG. 38, the rectifying and smoothing unit 150 may be located away from the power receiving coil unit 140 and the RF filter 200. Alternatively, as shown in FIG. 39, the rectifying and smoothing unit 150 may be integrated with the RF filter 200 and the power receiving coil unit 140. That is, the rectifying and smoothing unit 150, the RF filter 200, and the power receiving coil unit 140 may all be disposed within a single metal housing, or may be provided on a single circuit board.

Also in the embodiments shown in each of FIGS. 38 and 39, the power transmitting coil unit 130, the power receiving coil unit 140, the rectifying and smoothing unit 150, the RF filter 200, the electricity storage unit 160, the pair of power feeding lines connecting the power receiving coil unit 140 and the rectifying and smoothing unit 150, the pair of power feeding lines connecting the rectifying and smoothing unit 150 and the RF filter 200, and the pair of power feeding lines connecting the RF filter 200 and the electricity storage unit 160 may each have an insulation distance with respect to the ground frame 110 and the metal housing 115. This may reduce common mode noise. Moreover, the RF filter 200 may provide a high impedance to high frequency power. Accordingly, the loss of high frequency power may be suppressed, and a high processing rate (for example, etching rate) may be obtained.

### [High-Efficiency Transmission of High Power]

In the plasma processing apparatus according to various exemplary embodiments, the power transmission voltage may be set to a high voltage level in order to transmit high power with high efficiency. Accordingly, the withstand voltage of each portion of the plasma processing apparatus may be improved. For example, as described above, the electricity storage unit 160 may include the plurality of capacitors connected in series between the positive line 160p and the negative line 160m that configure the pair of power feeling lines.

Furthermore, the positive line and the negative line constituting the pair of power feeding lines may have the same length and may have an insulation distance therebetween. This increases the withstand voltage against conductive noise.

Furthermore, the withstand voltage of each of the power transmitting coil 131 and the power receiving coil 141 may be increased by selecting the line-to-line pitch of windings constituting the same and the material and thickness of the coating or film of the windings. Additionally, the capacitors of the low pass filter, such as the termination capacitors mentioned above, and the resonant capacitors are selected to have a withstand voltage equal to or greater than the transmission voltage. In order to increase the withstand voltage, the ferrite material of each of the power transmitting coil unit 130 and the power receiving coil unit 140 is disposed so as to have an insulation distance from the ground. Furthermore, in order to increase the withstand voltage, the thermally conductive sheets of the power transmitting coil unit 130 and the power receiving coil unit 140 are selected to have an insulation withstand voltage equal to or higher than the transmission voltage.

### [Conductive Noise Countermeasures for Electricity Storage Unit]

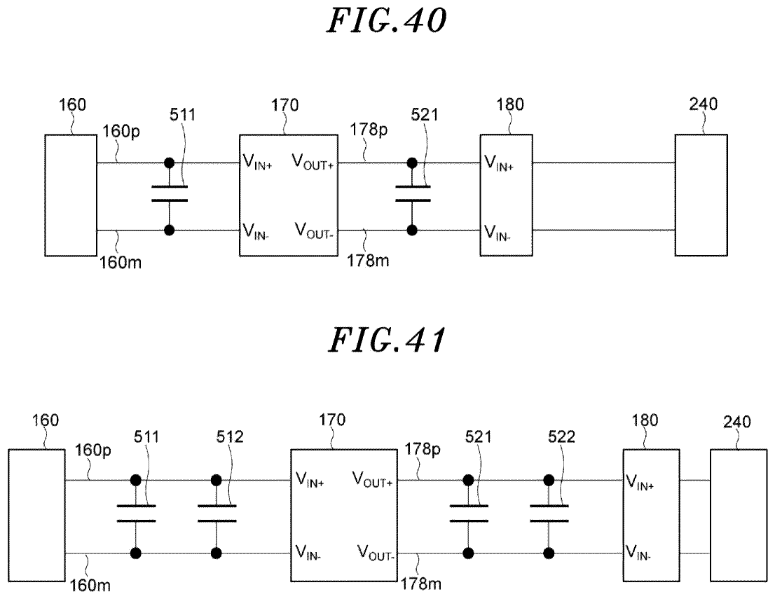

FIGS. 40 to 43 are referred. Each of FIGS. 40 to 43 is a diagram illustrating an exemplary embodiment for reducing a line-to-line potential difference due to conductive noise. The conductive noise may be caused by differences in impedance between positive and negative lines. In order to reduce the line-to-line potential difference between the positive line and the negative line due to such conductive noise, one or more capacitors may be connected between the positive line and the negative line that configure the power feeding line between the electricity storage unit 160 and the power consuming member 240. Each capacitor may be a non-polarized capacitor. The non-polar capacitor is selected from among a film capacitor, a ceramic capacitor, a multilayer ceramic capacitor, etc., depending on the frequency of the high frequency power used in the plasma processing apparatus. This reduces the line-to-line potential difference between the positive and negative lines caused by conductive noise.

For example, one or more capacitors may be connected between the positive line and the negative line connecting the electricity storage unit 160 and each of the one or more voltage controlled converters 170 to each other. Alternatively, or in addition, one or more capacitors may be connected between the positive and negative lines connecting each of one or more voltage controlled converters 170 and a corresponding constant voltage controller 180 to each other.

In the embodiment shown in FIG. 40, a capacitor 511 is connected between the positive line 160p and the negative line 160m which connect the electricity storage unit 160 and the voltage controlled converter 170 to each other. In addition, a capacitor 521 is connected between a positive line 178p and a negative line 178m which connect the voltage controlled converter 170 and the constant voltage controller 180 to each other. The positive line 178p connects the positive output (V_{OUT+}) of the voltage controlled converter 170 and the positive input (V_{IN+}) of the constant voltage controller 180 to each other. The negative line 178m connects the negative output (V_{OUT-}) of the voltage controlled converter 170 and the negative input (V_{IN-}) of the constant voltage controller 180 to each other. Each of capacitors 511 and 521 may be a non-polarized capacitor.

In the embodiment shown in FIG. 41, the capacitor 511 and the capacitor 512 are connected in parallel between the positive line 160p and the negative line 160m that connect the electricity storage unit 160 and the voltage controlled converter 170 to each other. The capacitor 511 and the capacitor 512 may have the same capacitance or may have different capacitances. In addition, the capacitor 521 and the capacitor 522 are connected in parallel between the positive line 178p and the negative line 178m which connect the voltage controlled converter 170 and the constant voltage controller 180 to each other. The capacitor 521 and the capacitor 522 may have the same capacitance or may have different capacitances. Each of the capacitors 511, 512, 521, and 522 may be a non-polarized capacitor. In addition, when two or more capacitors having different capacitances are connected in parallel between the positive line and the negative line, the two or more capacitors may be disposed so that the capacitor having the characteristic of reducing the line-to-line potential difference caused by the conductive noise with higher frequency is connected at a location where the electrical length from the power consuming member 240 is shorter. That is, a high frequency capacitor (a capacitor with a relatively small capacitance) may be disposed at a location closer to the power consuming member 240. In the embodiment shown in FIG. 41, when the capacitors 511 and 512 have different capacitances and the capacitors 521 and 522 have different capacitances, the capacitors 512 and 522 are high frequency capacitors, and the capacitors 511 and 521 are low frequency capacitors.

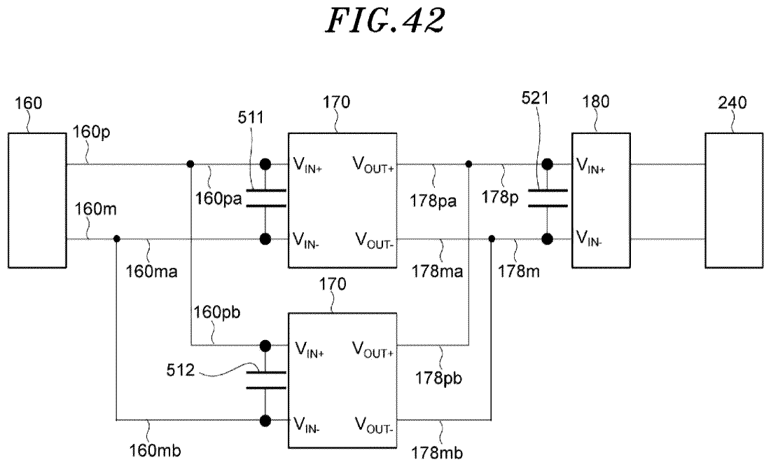

In the embodiment shown in FIG. 42, two voltage controlled converters 170 are connected in parallel between the electricity storage unit 160 and the constant voltage controller 180. The positive line 160p connected to the electricity storage unit 160 branches into positive lines 160pa and 160pb. The positive line 160pa is connected to the positive input (V_{IN+}) of one of two voltage controlled converters 170. The positive line 160pb is connected to the positive input (V_{IN+}) of the other of the two voltage controlled converters 170. The negative line 160m connected to the electricity storage unit 160 branches into negative lines 160ma and 160mb. The negative line 160ma is connected to the negative input (V_{IN-}) of one of two voltage controlled converters 170. The negative line 160mb is connected to the negative input (V_{IN-}) of the other of the two voltage controlled converters 170. Three or more voltage controlled converters 170 may be connected in parallel. In this connection, the maximum output powers of the three or more voltage controlled converters 170 may be the same as or different from one another.

In the embodiment shown in FIG. 42, the positive line 178p connected to the positive input (V_{IN+}) of the constant voltage controller 180 branches into positive lines 178pa and 178pb. The positive line 178pa is connected to the positive output (V_{OUT+}) of one of the two voltage controlled converters 170. The positive line 178pb is connected to the positive output (V_{OUT+}) of the other of the two voltage controlled converters 170. Furthermore, the negative line 178m connected to the negative input (V_{IN-}) of the constant voltage controller 180 branches into negative lines 178ma and 178mb. The negative line 178ma is connected to the negative output (V_{OUT-}) of one of the two voltage controlled converters 170. The negative line 178mb is connected to the negative output (V_{OUT-}) of the other of the two voltage controlled converters 170. In addition, each of the positive line 178p connected to the positive input (V_{IN+}) of the constant voltage controller 180 and the negative line 178m connected to the negative input (V_{IN-}) of the constant voltage controller 180 may branch into three or more lines.

In the embodiment shown in FIG. 42, the capacitor 511 is connected between the positive line 160pa and the negative line 160ma. In addition, the capacitor 512 is connected between the positive line 160pb and the negative line 160mb. In addition, the capacitor 521 is connected between the positive line 178p and the negative line 178m. Each of the capacitors 511, 512, and 521 may be a non-polarized capacitor. Furthermore, the capacitors 511, 512, and 521 may have the same capacitance or different capacitances.

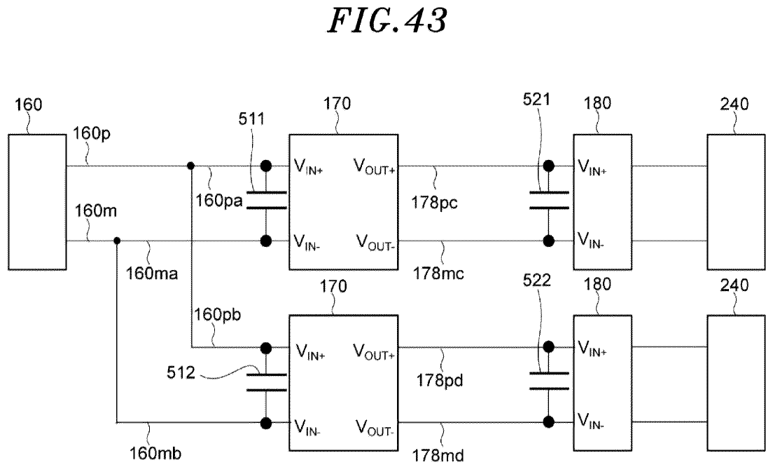

In the embodiment shown in FIG. 43, two power feeding systems are connected to the electricity storage unit 160. Each of the two power feeding systems include the voltage controlled converter 170 and the constant voltage controller 180. The two power feeding systems are connected to two power consuming members 240, respectively. That is, two voltage control converters 170 are connected to the electricity storage unit 160, two constant voltage controllers 180 are respectively connected to the two voltage control converters 170, and the two constant voltage controllers 180 are respectively connected to two power consuming members 240. Further, three or more power feeding systems may be connected to the electricity storage unit 160.

In the embodiment shown in FIG. 43, the positive line 160p connected to the electricity storage unit 160 branches into positive lines 160pa and 160pb. The positive line 160pa is connected to the positive input (V_{IN+}) of one of two voltage controlled converters 170. The positive line 160pb is connected to the positive input (V_{IN+}) of the other of the two voltage controlled converters 170. The negative line 160m connected to the electricity storage unit 160 branches into negative lines 160ma and 160mb. The negative line 160ma is connected to the negative input (V_{IN-}) of one of two voltage controlled converters 170. The negative line 160mb is connected to the negative input (V_{IN-}) of the other of the two voltage controlled converters 170.

In addition, in the embodiment shown in FIG. 43, a positive line 178pc connects the positive output (V_{OUT+}) of one of the two voltage controlled converters and the positive input (V_{IN+}) of one of the two constant voltage controllers 180 to each other. Furthermore, a negative line 178mc connects the negative output (V_{OUT-}) of one of the two voltage controlled converters and the negative input (V_{IN+}) of one of the two constant voltage controllers 180 to each other. Furthermore, a positive line 178pd connects the positive output (V_{OUT+}) of the other of the two voltage controlled converters and the positive input (V_{IN+}) of the other of the two constant voltage controllers 180 to each other. Furthermore, a negative line 178md connects the negative output (V_{OUT-}) of the other of the two voltage controlled converters and the negative input (V_{IN+}) of the other of the two constant voltage controllers 180 to each other.

In the embodiment shown in FIG. 43, the capacitor 511 is connected between the positive line 160pa and the negative line 160ma. In addition, the capacitor 512 is connected between the positive line 160pb and the negative line 160mb. In addition, the capacitor 521 is connected between the positive line 178pc and the negative line 178mc. In addition, the capacitor 522 is connected between the positive line 178pd and the negative line 178md. Each of the capacitors 511, 512, 521, and 522 may be a non-polarized capacitor. Furthermore, the capacitors 511, 512, 521, and 522 may have the same capacitance or different capacitances.

### [Countermeasures for Load Fluctuations in Rectifying and Smoothing Unit]

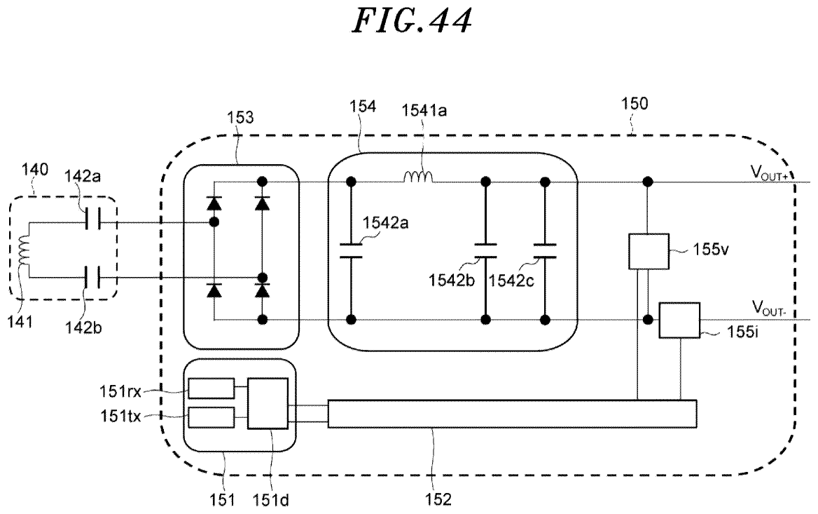

FIGS. 14 and 44 to 46 are referred. FIGS. 44 to 46 are diagrams illustrating a rectifying and smoothing unit according to another exemplary embodiment. The voltage after rectification by the rectifying circuit 153 of the rectifying and smoothing unit 150 (the output voltage of the rectifying circuit 153) has an amplitude that fluctuates at a frequency twice the transmission frequency. The smoothing circuit 154 may be configured to reduce the fluctuation (amplitude) of the output voltage even when the above-mentioned load fluctuation occurs. This enables the rectifying and smoothing unit 150 to feed power even when a load fluctuation occurs, and ensures a withstand voltage margin for the electricity storage unit 160.

Specifically, the smoothing circuit 154 is configured so as to satisfy the condition that the ratio (amplitude ratio) of the amplitude of the output voltage of the smoothing circuit 154 to the amplitude of the output voltage of the rectifying circuit 153 is 3% or less. Moreover, the smoothing circuit 154 is configured so as to satisfy the condition that the cutoff frequency/(2×transmission frequency) is smaller than 1/10.

In each of the embodiments shown in FIGS. 14 and 44 to 46, the capacitance of at least one smoothing capacitor is set so that the smoothing circuit 154 has the above-mentioned characteristics. In the embodiments shown in each of FIGS. 14, 45, and 46, the capacitance of the capacitor 1542b is set so that the smoothing circuit 154 has the above-mentioned characteristics. In the embodiment shown in FIG. 44, the capacitor 1542b and the capacitor 1542c are connected in parallel between the positive line and the negative line between the inductor 1541a and the positive output (V_{OUT+}) of the rectifying and smoothing unit 150. The combined capacitance of the capacitors 1542b and 1542c is set so that the smoothing circuit 154 has the above-mentioned characteristics.

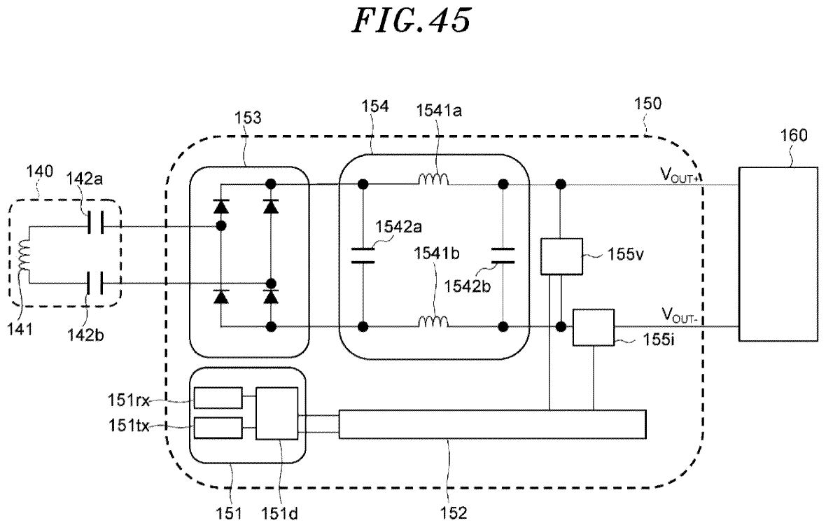

In the rectifying and smoothing unit 150 shown in FIG. 45, an inductor 1541b is connected between the other end of the capacitor 1542a and the other end of the capacitor 1542b. The rectifying and smoothing unit 150 shown in FIG. 45 does not need to have the capacitor 1542a. The rectifying and smoothing unit 150 shown in FIG. 45 does not need to have the capacitor 1542a and the inductor 1541b. The rectifying and smoothing unit 150 shown in FIG. 45 does not need to have the inductors 1541a and 1541b.

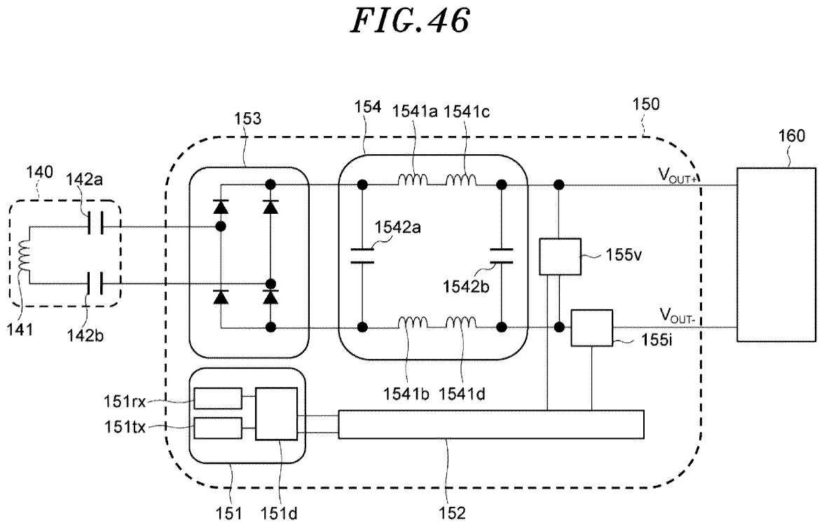

In the rectifying and smoothing unit 150 shown in FIG. 46, the inductor 1541a and the inductor 1541c are connected in series between one end of the capacitor 1542a and one end of the capacitor 1542b. In addition, an inductor 1541v and an inductor 1541d are connected in series between the other end of the capacitor 1542a and the other end of the capacitor 1542b. The rectifying and smoothing unit 150 shown in FIG. 46 does not need to have the inductors 1541b and 1541d.

### [Synchronous Control of Constant Voltage Controller]

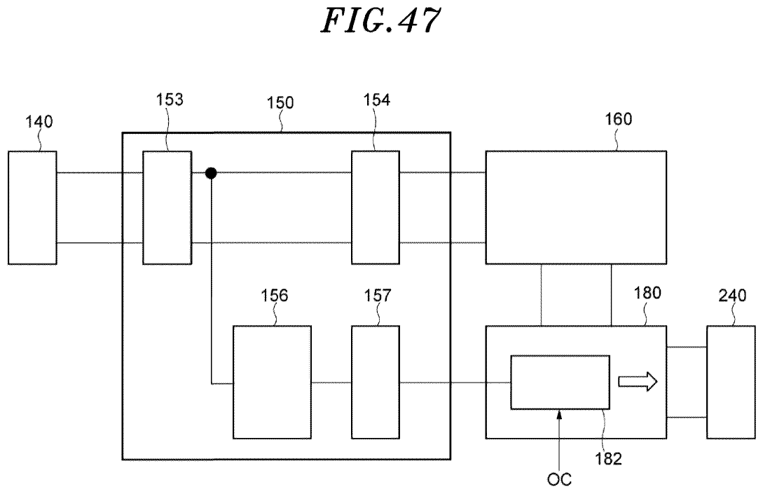

FIG. 47 is referred. FIG. 47 is a diagram illustrating a rectifying and smoothing unit and a constant voltage controller according to another exemplary embodiment. In the embodiment shown in FIG. 47, the constant voltage controller 180 is configured to control the application of voltage to the power consuming member 240 and the stop of voltage application in synchronization with the transmission AC power transmitted between the power transmitting coil unit 130 and the power receiving coil unit 140. In this embodiment, the rectifying and smoothing unit 150 may include a synchronous pulse generator 156. Further, the rectifying and smoothing unit 150 may further include a level adjustment unit 157.

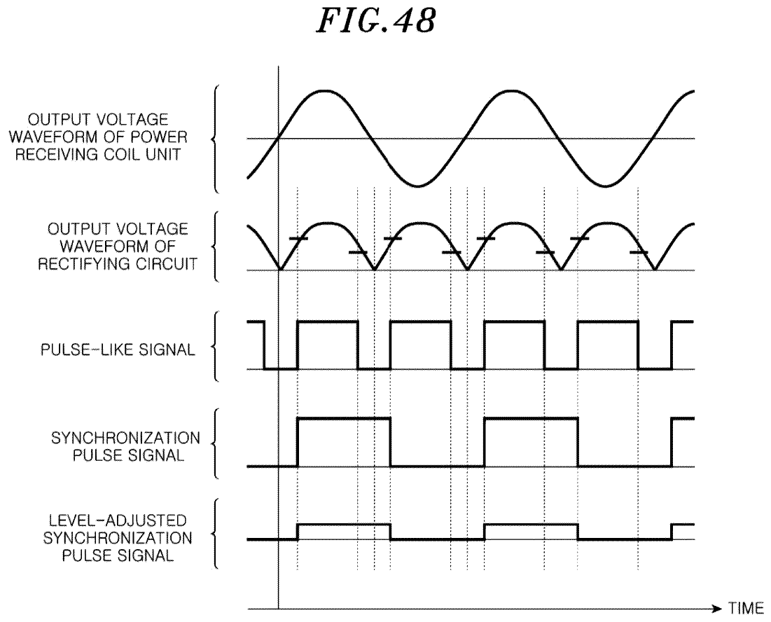

FIG. 48 is a timing chart of an example of a signal output from each portion of the rectifying and smoothing unit and an output voltage in a power receiving coil unit. As shown in FIG. 48, the output power of the power receiving coil unit 140 has a transmission frequency. The rectifying circuit 153 outputs a voltage having a frequency twice the transmission frequency by full-wave rectification of the output power of the power receiving coil unit 140. The synchronous pulse generator 156 generates a pulse-like signal from the output voltage of the rectifying circuit 153. Specifically, the synchronous pulse generator 156 generates a pulse-like signal that rises when the output voltage of the rectifying circuit 153 has a first reference voltage level while its voltage level is rising, and that falls when the output voltage of the rectifying circuit 153 has a second reference voltage level while its voltage level is falling. The synchronous pulse generator 156 generates a synchronization pulse signal that alternately transitions between an ON state and an OFF state at the rising edge of the pulse-like signal. The signal level of the synchronization pulse signal may be adjusted in the level adjustment unit 157.

The constant voltage controller 180 shown in FIG. 47 is configured to adjust the timing of applying and stopping the voltage application to the power consuming member 420 based on the synchronization pulse signal (or a level-adjusted synchronization pulse signal).

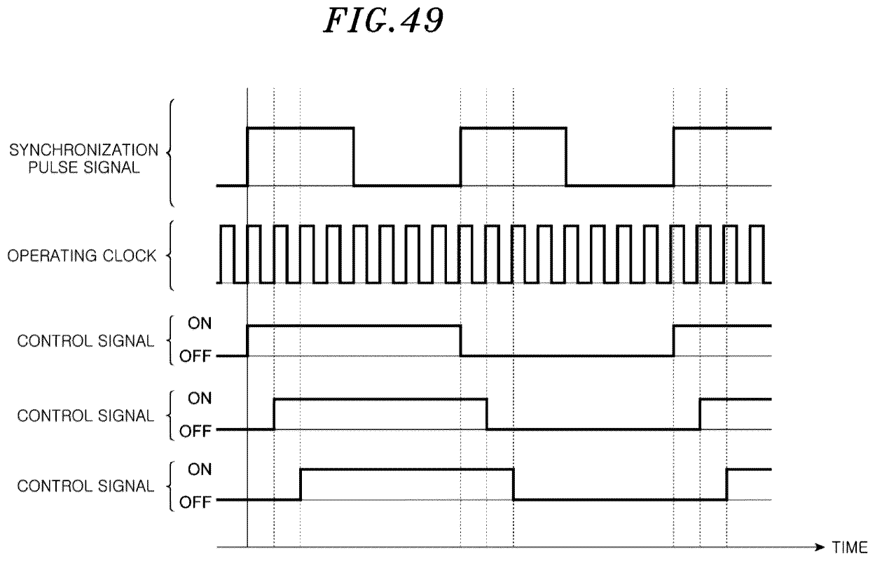

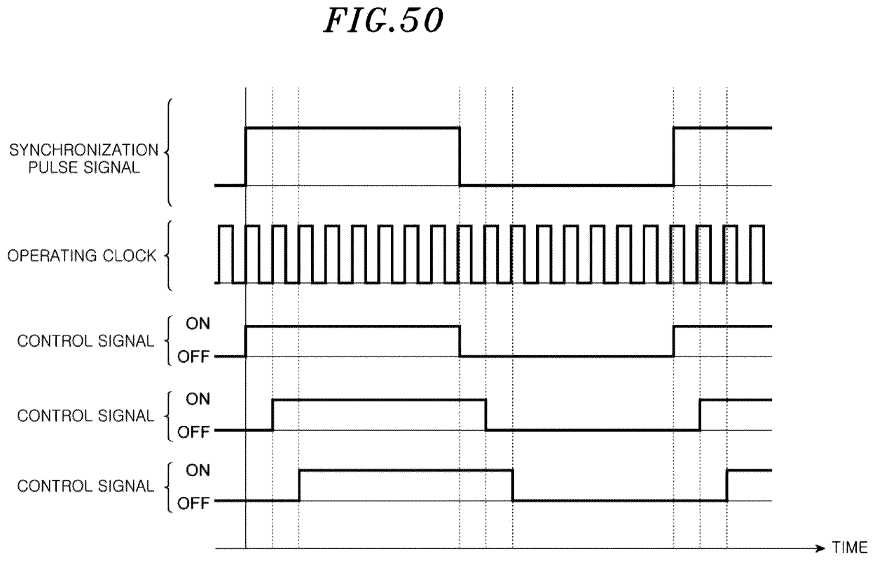

Each of FIGS. 49 and 50 is an exemplary timing chart related to the constant voltage controller shown in FIG. 47. In each of FIGS. 49 and 50, an operating clock is an operating clock OC (see FIG. 47) of the controller 182 of the constant voltage controller 180. In each of FIGS. 49 and 50, each control signal is a signal for applying and stopping the application of voltage to the corresponding power consuming member 240. When the control signal has an ON state, a voltage is applied from the constant voltage controller 180 to the corresponding power consuming member 240, and when the control signal has an OFF state, the application of voltage from the constant voltage controller 180 to the corresponding power consuming member 240 is stopped.

In the embodiment shown in FIG. 49, the controller 182 generates a plurality of control signals that alternately transitions between an ON state and an OFF state with a period of the synchronization pulse signal (or a level-adjusted synchronization pulse signal), that is, a period twice the transmission AC power. The controller 182 sets a delay amount of each control signal so that the control signal has the delay amount that is an integer multiple of the period of the operating clock relative to the synchronization pulse signal (or the level-adjusted synchronization pulse signal). This makes it possible to arbitrarily control the timing of voltage application from the constant voltage controller 180 to the power consuming member 240. Accordingly, it is possible to synchronize the timing of voltage application to a specific power consuming member 240 or to individually adjust the timing of voltage application to the specific power consuming member 240, thereby making it possible to achieve efficiency and/or high performance of control of the power consuming member 240. In addition, the constant voltage controller 180 may be in communication with the controller 2 of the plasma processing system. In this connection, the constant voltage controller 180 may select synchronous or asynchronous control of the power consuming member 240 and other units that may communicate with the controller 2, making it possible to optimize plasma processing and/or avoid concentration of power in use. The other units are, for example, the first RF generator 31a, the second RF generator 32a, the gas supply portion 20 and/or the exhaust system 40.

In the embodiment shown in FIG. 50, the controller 182 generates a plurality of control signals that alternately transitions between an ON state and an OFF state with a period of the synchronization pulse signal (or a level-adjusted synchronization pulse signal), that is, a period of the transmission AC power. The controller 182 sets a delay amount of each control signal so that the control signal has the delay amount that is an integer multiple of the period of the operating clock relative to the synchronization pulse signal (or the level-adjusted synchronization pulse signal). This makes it possible to arbitrarily control the timing of voltage application from the constant voltage controller 180 to the power consuming member 240. Accordingly, it is possible to synchronize the timing of voltage application to the specific power consuming member 240 or to individually adjust the timing of voltage application to the specific power consuming member 240, thereby making it possible to achieve efficiency and/or high performance of control of the power consuming member 240. In addition, the constant voltage controller 180 may be in communication with the controller 2 of the plasma processing system. In this connection, the constant voltage controller 180 may select synchronous or asynchronous control of the power consuming member 240 and other units that may communicate with the controller 2, making it possible to optimize plasma processing and/or avoid concentration of power in use. The other units are, for example, the first RF generator 31a, the second RF generator 32a, the gas supply portion 20 and/or the exhaust system 40.

[Electricity Storage Unit having Non-Polarized Capacitor]

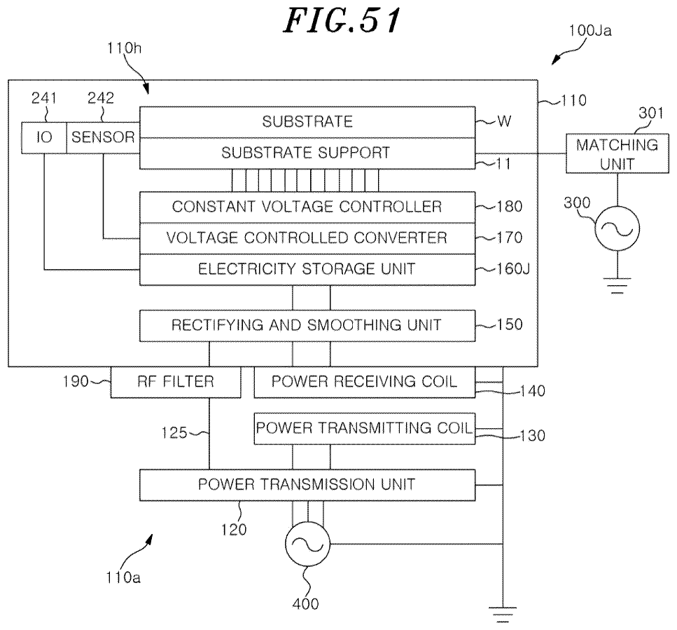

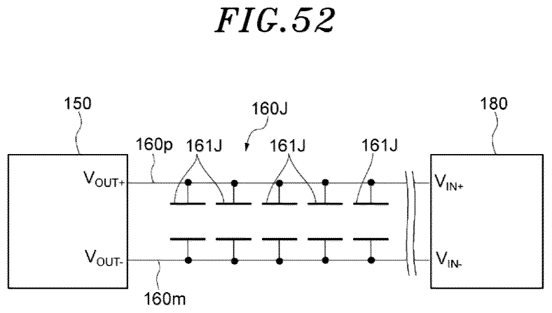

FIGS. 51 and 52 are referred. FIG. 51 is a diagram schematically illustrating a plasma processing apparatus according to yet another exemplary embodiment. FIG. 52 is a diagram illustrating an electricity storage unit in a plasma processing apparatus according to yet another exemplary embodiment. Hereinafter, a plasma processing apparatus 100Ja shown in FIG. 51 will be described from the viewpoint of its differences from the plasma processing apparatus 100C (see FIG. 5).

The plasma processing apparatus 100Ja includes an electricity storage unit 160J instead of the electricity storage unit 160. As shown in FIG. 52, the electricity storage unit 160J includes a plurality of non-polarized capacitors 161J. The plurality of non-polarized capacitors 161J are connected in parallel between the positive line 160p and the negative line 160m. Each of the plurality of non-polarized capacitors 161J is selected from a film capacitor, a ceramic capacitor, a multilayer ceramic capacitor, or the like. Such electricity storage unit 160J has a high withstand voltage. Furthermore, the plurality of non-polarized capacitors 161J may have the same capacitance or different capacitances.

In addition to the power consuming member 240, the plasma processing apparatus 100Ja includes one or more input/output devices 241 and one or more sensors 242 as separate power consuming members. The one or more input/output devices 241 include one or more of an actuator (stepping motor or servo motor) used in the plasma processing apparatus 100Ja, a light-emitting device, a control circuit, a power generator for each input/output device 241, a power supply for the electrostatic chuck, a switch, and a thermistor. The one or more sensors 242 include one or more of a variety of sensors and cameras that detect conditions within the chamber 10. A DC voltage is applied to each of the one or more input/output devices 241 and the one or more sensors 242 from any one of the electricity storage unit 160J, the voltage controlled converter 170, and the constant voltage controller 180.

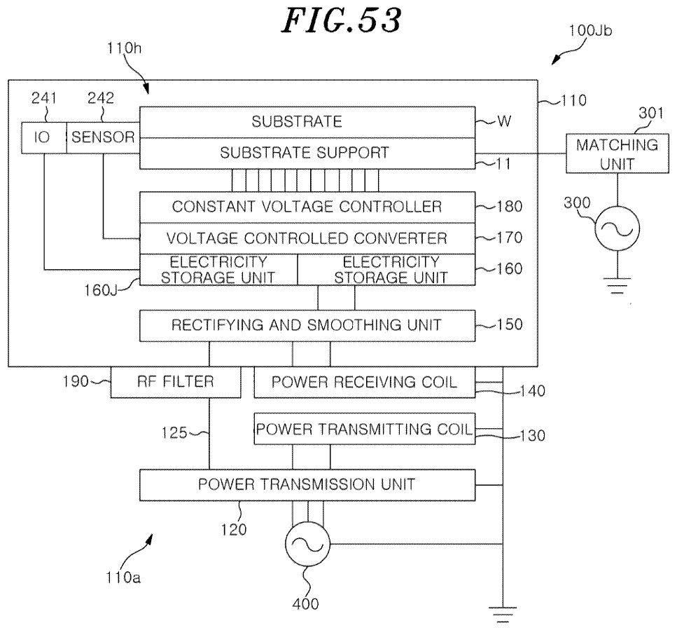

FIG. 53 is referred. FIG. 53 is a diagram schematically illustrating a plasma processing apparatus according to yet another exemplary embodiment. Hereinafter, a plasma processing apparatus 100Jb shown in FIG. 53 will be described from the viewpoint of its differences from the plasma processing apparatus 100Ja.

The plasma processing apparatus 100Jb includes the above-mentioned electricity storage unit 160 in addition to the electricity storage unit 160J. A voltage is applied from the constant voltage controller 180 to the power consuming member 240 such as a heater that requires a relatively large amount of power, using the power stored in the electricity storage unit 160. For the power consuming member that requires a relatively small amount of power, such as one or more input/output devices 241 and one or more sensors 242, a DC voltage is applied from either the electricity storage unit 160J, the voltage controlled converter 170, or the constant voltage controller 180, using the power stored in the electricity storage unit 160J.

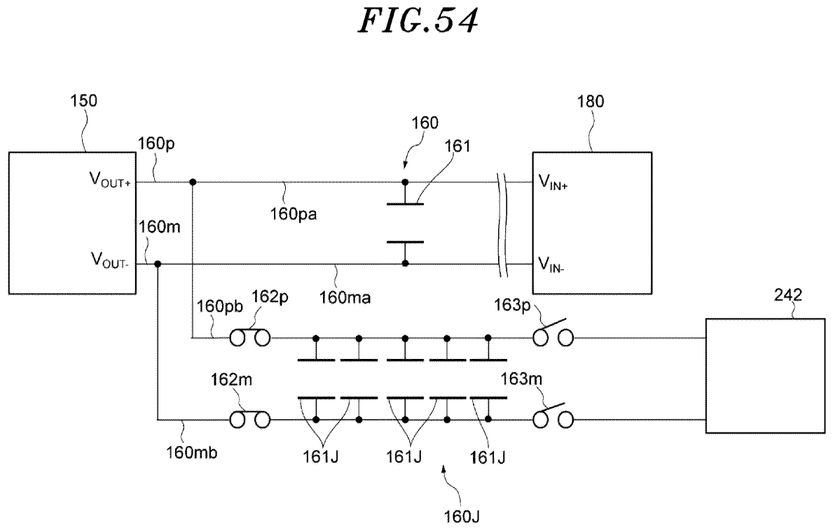

FIG. 54 is referred. FIG. 54 is a diagram illustrating an electricity storage unit in a plasma processing apparatus according to yet another exemplary embodiment. As shown in FIG. 54, the positive line 160p connected to the positive output (V_{OUT+}) of the rectifying and smoothing unit 150 branches into the positive line 160pa and the positive line 160pb. The positive line 160pa is a portion of the positive line connected between the rectifying and smoothing unit 150 and the constant voltage controller 180. The positive line 160pb is a portion of the positive line connected between the rectifying and smoothing unit 150 and the sensor 242. The negative line 160m connected to the negative output (V_{OUT-}) of the rectifying and smoothing unit 150 branches into the negative line 160ma and the negative line 160mb. The negative line 160ma is a portion of the negative line connected between the rectifying and smoothing unit 150 and the constant voltage controller 180. The negative line 160mb is a portion of the negative line connected between the rectifying and smoothing unit 150 and the sensor 242.

The electricity storage unit 160 includes at least one capacitor 161 which is a polarized capacitor. As described above in relation to the plasma processing apparatus 100Jb, a voltage is applied from the constant voltage controller 180 to the power consuming member 240 such as a heater that requires a relatively large amount of power, using the power stored in the electricity storage unit 160.

The positive line 160pb includes a switch 162p and a switch 163p. The negative line 160mb includes a switch 162m and a switch 163m. The electricity storage unit 160J is connected to the positive line 160pb between the switch 162p and the switch 163p. Furthermore, the electricity storage unit 160J is connected to the negative line 160mb between the switch 162m and the switch 163m.

The switches 162p and 162m are closed until charging of the electricity storage unit 160J is completed. The opening and closing of the switches 162p and 162m is controlled by the controller 152 of the rectifying and smoothing unit 150. The switches 163p and 163m are open when the plasma processing apparatus is in normal operation state. That is, when the plasma processing apparatus is in a normal operation state, the application of voltage from the electricity storage unit 160J to one or more sensors 242 is stopped. When an abnormality is detected in the plasma processing apparatus, the switches 163p and 163m are closed by a signal from a control mechanism such as an interlock mechanism. Thus, when an abnormality is detected in the plasma processing apparatus, a voltage is applied to one or more sensors 242, data from within the chamber 10 of the plasma processing apparatus is acquired, and the data is logged. In this manner, the electricity storage unit 160J may be used as an electricity storage unit for low power for data acquisition and data logging of one or more sensors 242 disposed at locations exposed to high frequency energy.

### [Plasma Processing Apparatus Including Plurality of Voltage Controlled Converters]

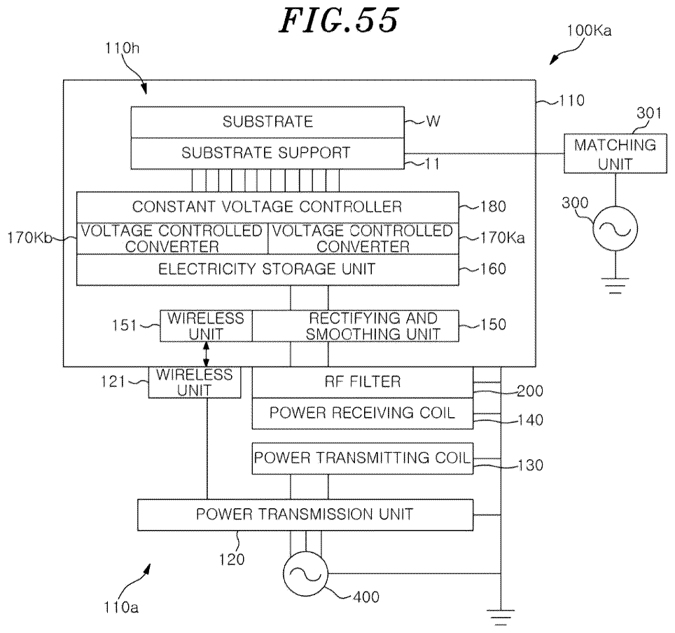

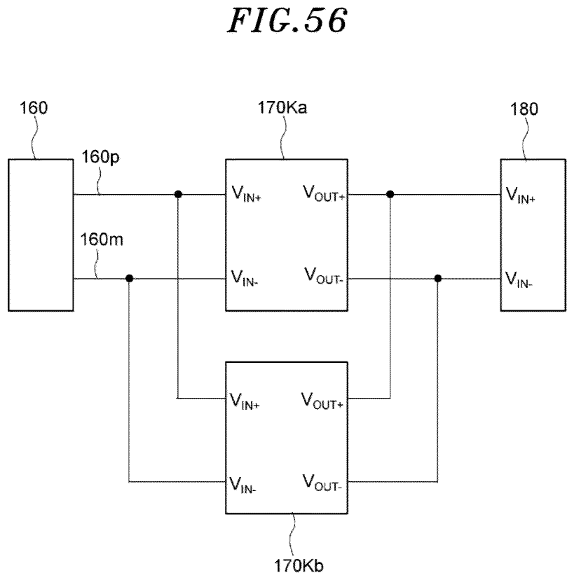

FIGS. 55 and 56 are referred. FIG. 55 is a diagram schematically illustrating a plasma processing apparatus according to yet another exemplary embodiment. FIG. 56 is a diagram illustrating a connection of a plurality of voltage control converters in a plasma processing apparatus according to yet another exemplary embodiment. Hereinafter, a plasma processing apparatus 100Ka shown in FIG. 55 will be described from the viewpoint of its differences from the plasma processing apparatus 100E (see FIG. 7).

The plasma processing apparatus 100Ka includes a plurality of voltage controlled converters 170Ka and 170Kb. Each of the plurality of voltage controlled converters 170Ka, 170Kb has the same configuration as the voltage controlled converter 170. The plurality of voltage control converters 170Ka, 170Kb are connected in parallel between the electricity storage unit 160 and the constant voltage controller 180.

As shown in FIG. 56, the positive line 160p is connected to the positive input (V_{IN+}) of each of the plurality of voltage controlled converters 170Ka, 170Kb. The negative line 160m is connected to the negative input (V_{IN-}) of each of the plurality of voltage controlled converters 170Ka, 170Kb. The positive output (V_{OUT+}) of each of the plurality of voltage controlled converters 170Ka, 170Kb is connected to the positive input (V_{IN+}) of the constant voltage controller 180. The negative output (V_{OUT-}) of each of the plurality of voltage controlled converters 170Ka, 170Kb is connected to the negative input (V_{IN-}) of the constant voltage controller 180.

According to the plasma processing apparatus 100Ka, a large output current capacity may be obtained by connecting the plurality of voltage controlled converters 170Ka, 170Kb in parallel, and thus a large maximum output power may be obtained. The maximum output powers of the plurality of voltage controlled converters 170Ka, 170Kb may be the same as each other or may be different from each other.

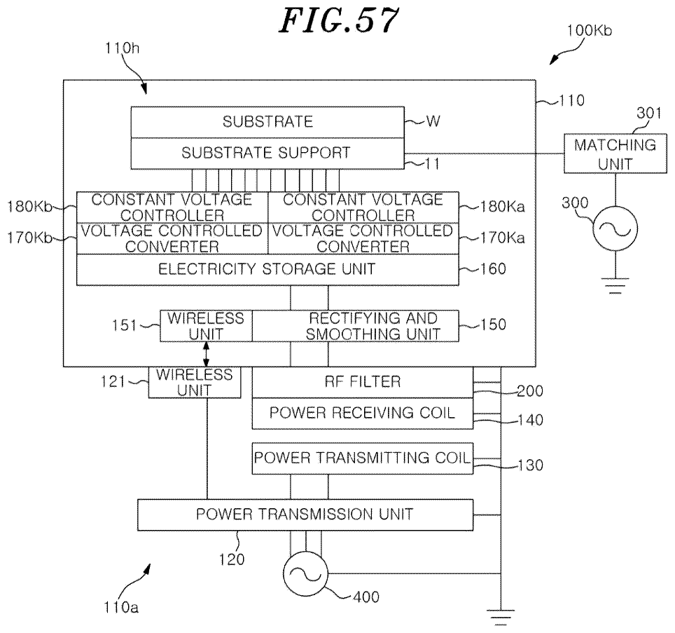

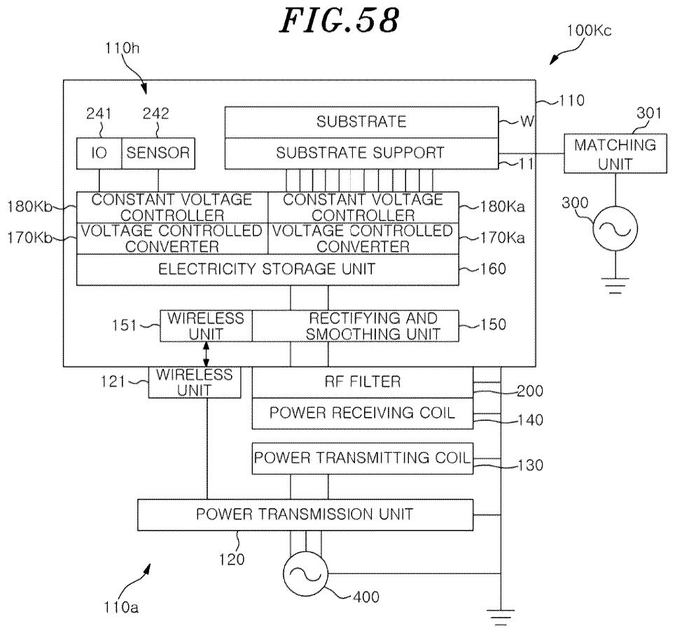

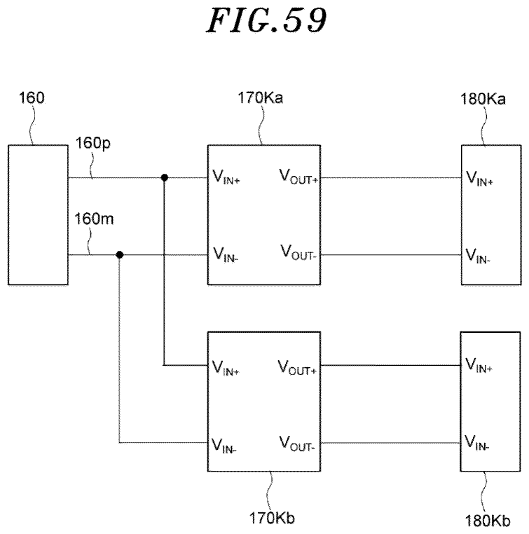

FIGS. 57 to 59 are referred. FIG. 57 is a diagram schematically illustrating a plasma processing apparatus according to yet another exemplary embodiment. FIG. 58 is a diagram schematically illustrating a plasma processing apparatus according to yet another exemplary embodiment. FIG. 59 is a diagram illustrating a connection of a plurality of voltage control converters in a plasma processing apparatus according to yet another exemplary embodiment. Hereinafter, a plasma processing apparatus 100Kb shown in FIG. 57 and a plasma processing apparatus 100Kc shown in FIG. 58 will be described from the viewpoint of their differences from the plasma processing apparatus 100Ka.

In each of the plasma processing apparatuses 100 Kb, 100 Kc, a plurality of power feeding systems are connected to the electricity storage unit 160. Specifically, each of the plasma processing apparatuses 100Kb and 100Kc includes a plurality of constant voltage controllers 180Ka, 180Kb. One of the plurality of power feeding systems includes the voltage controlled converter 170Ka and the constant voltage controller 180Ka. Another one of the plurality of power feeding systems includes the voltage controlled converter 170Kb and the constant voltage controller 180Kb.

As shown in FIG. 59, the positive line 160p is connected to the positive input (V_{IN+}) of each of the plurality of voltage controlled converters 170Ka, 170Kb. The negative line 160m is connected to the negative input (V_{IN-}) of each of the plurality of voltage controlled converters 170Ka, 170Kb. The positive output (V_{OUT+}) of the voltage controlled converter 170Ka is connected to the positive input (V_{IN+}) of the constant voltage controller 180Ka, and the negative output (V_{OUT-}) of the voltage controlled converter 170Ka is connected to the negative input (V_{IN-}) of the constant voltage controller 180Ka. The positive output (V_{OUT+}) of the voltage controlled converter 170Kb is connected to the positive input (V_{IN+}) of the constant voltage controller 180Kb, and the negative output (V_{OUT-}) of the voltage controlled converter 170Kb is connected to the negative input (V_{IN-}) of the constant voltage controller 180Kb.

As shown in FIG. 57, in the plasma processing apparatus 100Kb, the plurality of constant voltage controllers 180Ka and 180Kb are connected to one or more power consuming members 240, such as one or more heaters, provided within the substrate support 11. As shown in FIG. 58, in the plasma processing apparatus 100Kc, the constant voltage controller 180Ka is connected to one or more power consuming members 240 such as one or more heaters provided in the substrate support 11. Further, in the plasma processing apparatus 100Kc, the constant voltage controller 180Kb is connected to at least one input/output device 241 and/or at least one sensor 242.

According to the plasma processing apparatuses 100Kb and 100Kc, a large maximum output power may be obtained by using the plurality of power feeding systems. Furthermore, according to the plasma processing apparatuses 100Kb and 100Kc, it is possible to control the voltage application to the power consuming members separately for each power feeding system.

### [Plasma Processing Apparatus Including Plurality of Power Transmitting Coils and Plurality of Power Receiving Coils]

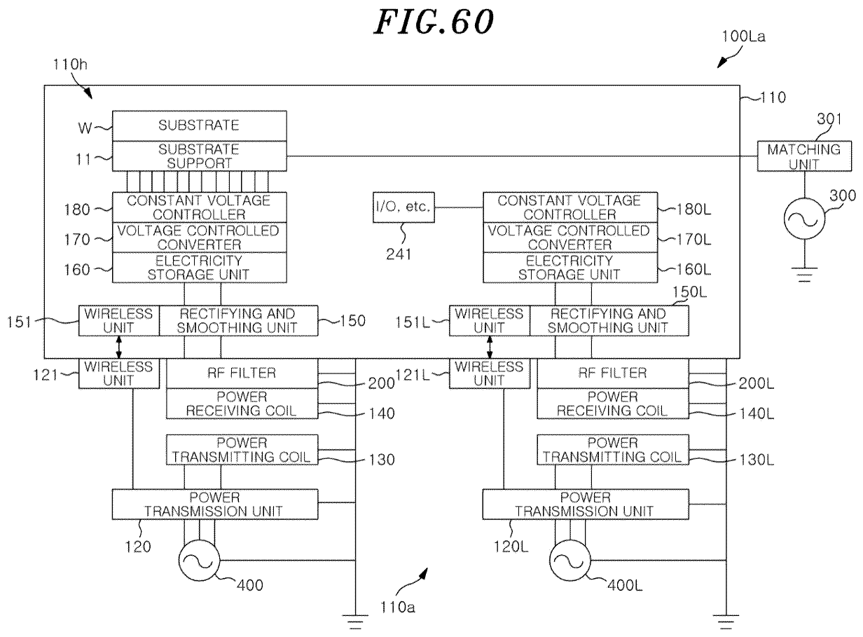

FIG. 60 is referred. FIG. 60 is a diagram schematically illustrating a plasma processing apparatus according to yet another exemplary embodiment. Hereinafter, a plasma processing apparatus 100La shown in FIG. 60 will be described from the viewpoint of its differences from the plasma processing apparatus 100E (see FIG. 7).

The plasma processing apparatus 100La further includes a power transmission unit 120L having a communication unit 121L, a power transmitting coil unit 130L, a power receiving coil unit 140L, an RF filter 200L, a rectifying and smoothing unit 150L having a communication unit 151L, an electricity storage unit 160L, a voltage controlled converter 170L, and a constant voltage controller 180L. The power transmission unit 120L, the communication unit 121L, the power transmitting coil unit 130L, the power receiving coil unit 140L, the RF filter 200L, the rectifying and smoothing unit 150L, the communication unit 151L, the electricity storage unit 160L, the voltage controlled converter 170L, and the constant voltage controller 180L are configured in the same manner as the power transmission unit 120, the communication unit 121, the power transmitting coil unit 130, the power receiving coil unit 140, the RF filter 200, the rectifying and smoothing unit 150, the communication unit 151, the electricity storage unit 160, the voltage controlled converter 170, and the constant voltage controller 180, respectively.

The power transmission unit 120, the power transmitting coil unit 130, the power receiving coil unit 140, the RF filter 200, the rectifying and smoothing unit 150, the electricity storage unit 160, the voltage controlled converter 170, and the constant voltage controller 180 configure a first power feeding system. The power transmission unit 120L, the power transmitting coil unit 130L, the power receiving coil unit 140L, the RF filter 200L, the rectifying and smoothing unit 150L, the electricity storage unit 160L, the voltage controlled converter 170L, and the constant voltage controller 180L configure a second power feeding system.

In the second power feeding system, the power transmission unit 120L generates transmission AC power from an AC power supply 400L. The power transmission unit 120L is connected to the power transmitting coil unit 130L, and the power transmitting coil unit 130L is electromagnetically inductively coupled to the power receiving coil unit 140L. The power receiving coil unit 140L is connected to the rectifying and smoothing unit 150L via the RF filter 200L. The electricity storage unit 160L is connected between the rectifying and smoothing unit 150L and the voltage controlled converter 170L. The constant voltage controller 180L is connected to at least one input/output device 241 and/or at least one sensor 242.

The plasma processing apparatus 100La has the plurality of power feeding systems, each of which includes the power transmitting coil unit and the power receiving coil unit. Accordingly, the plasma processing apparatus 100La may employ small-sized coils as each power transmitting coil and each the power receiving coil, thereby increasing the degree of freedom in the layout of the disposition. Moreover, it is possible to supply high power by wireless power feeding. Each of the plurality of power feeding systems may supply the same power or different powers.

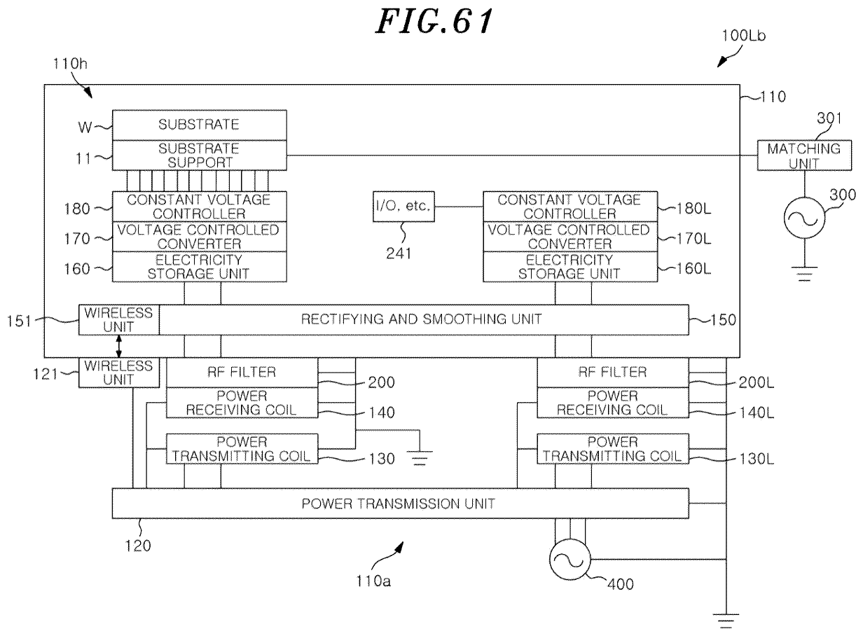

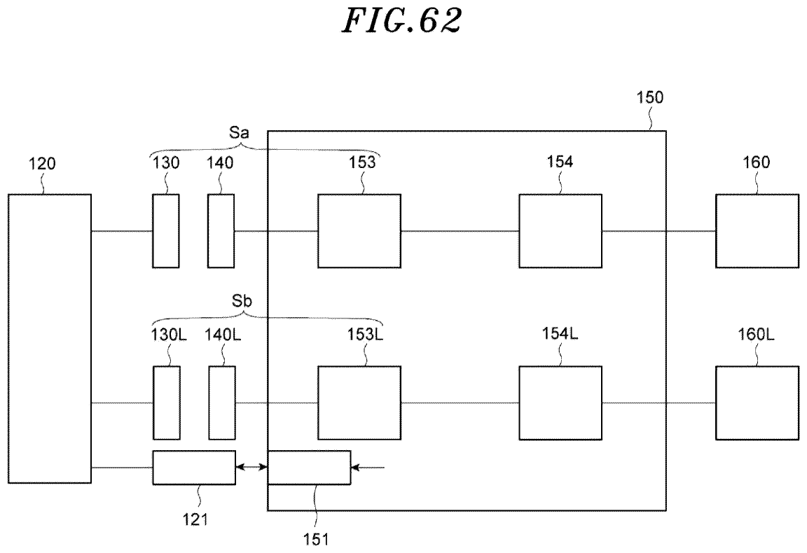

FIGS. 61 and 62 are referred. FIG. 61 is a diagram schematically illustrating a plasma processing apparatus according to yet another exemplary embodiment. FIG. 62 is a diagram illustrating a rectifying and smoothing unit according to yet another exemplary embodiment. Hereinafter, a plasma processing apparatus 100Lb shown in FIG. 61 will be described from the viewpoint of its differences from the plasma processing apparatus 100La.

The plasma processing apparatus 100Lb includes the first power feeding system and the second power feeding system, similar to the plasma processing apparatus 100La. However, in the plasma processing apparatus 100Lb, a single rectifying and smoothing unit 150 is connected between the RF filter 200 and the electricity storage unit 160 and between the RF filter 200L and the electricity storage unit 160L. That is, the first power feeding system and the second power feeding system share the rectifying and smoothing unit 150. In the plasma processing apparatus 100Lb, a single power transmission unit 120 is connected to the power transmitting coil unit 130 and the power transmitting coil unit 130L. That is, the first power feeding system and the second power feeding system share the power transmission unit 120.

As shown in FIG. 62, in the plasma processing apparatus 100Lb, the rectifying and smoothing unit 150 further includes a rectifying circuit 153L and a smoothing circuit 154L. The rectifying circuit 153L and the smoothing circuit 154L are configured similarly to the rectifying circuit 153 and the smoothing circuit 154, respectively. The rectifying circuit 153 is connected to the smoothing circuit 154, and the smoothing circuit 154 is connected to the electricity storage unit 160. Moreover, the rectifying circuit 153L is connected to the smoothing circuit 154L, and the smoothing circuit 154L is connected to the electricity storage unit 160L.

In the plasma processing apparatus 100Lb, the rectifying and smoothing unit 150 may transmit an instruction signal to the power transmission unit 120 to individually control the power feeding by the power feeding system including the power transmitting coil unit 130 and the power feeding by the power feeding system including the power transmitting coil unit 130L.

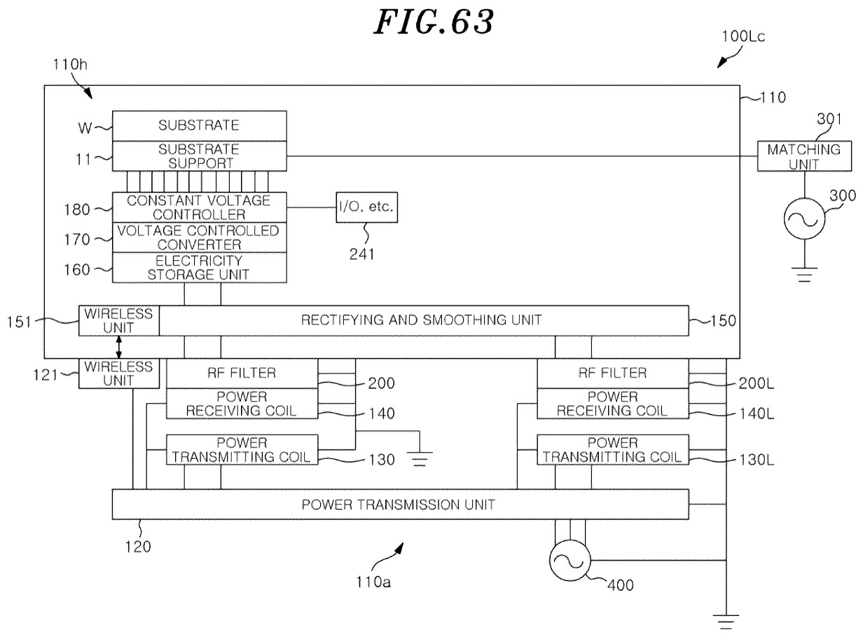

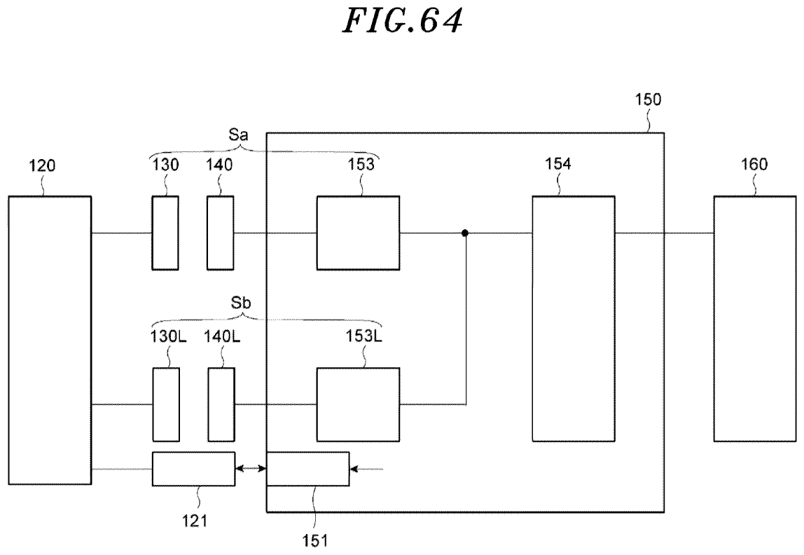

FIGS. 63 and 64 are referred. FIG. 63 is a diagram schematically illustrating a plasma processing apparatus according to yet another exemplary embodiment. FIG. 64 is a diagram schematically illustrating a rectifying and smoothing unit according to yet another exemplary embodiment. Hereinafter, the plasma processing apparatus 100Lc shown in FIG. 63 will be described from the viewpoint of its differences from the plasma processing apparatus 100Lb.

The plasma processing apparatus 100Lc includes the first power feeding system and the second power feeding system, similar to the plasma processing apparatus 100Lb. However, in the plasma processing apparatus 100Lc, the first power feeding system and the second power feeding system share the rectifying and smoothing unit 150, the electricity storage unit 160, the voltage controlled converter 170, and the constant voltage controller 180. Specifically, the rectifying and smoothing unit 150 is connected between the RF filter 200 and the electricity storage unit 160, and between the RF filter 200L and the electricity storage unit 160L.

As shown in FIG. 64, in the plasma processing apparatus 100Lc, the rectifying and smoothing unit 150 includes the rectifying circuit 153L in addition to the rectifying circuit 153 and the smoothing circuit 154. The rectifying circuit 153 is connected between the power receiving coil unit 140 and the smoothing circuit 154, and the rectifying circuit 153L is connected between the power receiving coil unit 140L and the smoothing circuit 154. Further, the rectifying circuit 153L may be connected to the electricity storage unit 160 via a separate smoothing circuit 154L.

In the plasma processing apparatus 100Lc, the rectifying and smoothing unit 150 may transmit an instruction signal to the power transmission unit 120 to individually control the power feeding by the power feeding system including the power transmitting coil unit 130 and the power feeding by the power feeding system including the power transmitting coil unit 130L.

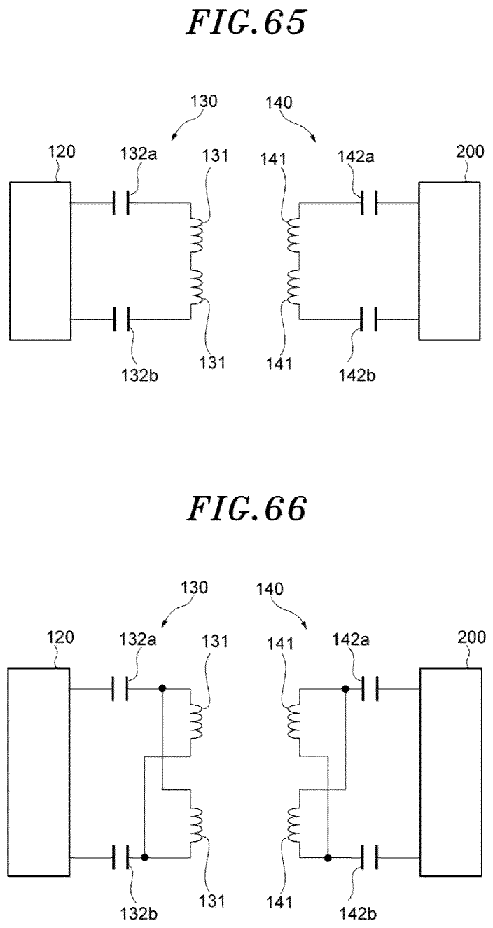

FIG. 65 is referred. FIG. 65 is a diagram illustrating a power receiving coil unit and a power transmitting coil unit in a plasma processing apparatus according to yet another exemplary embodiment. In the embodiment shown in FIG. 65, the power transmitting coil unit 130 includes a plurality of power transmitting coils 131. The plurality of power transmitting coils 131 are connected in series between the resonant capacitors 132a and 132b. Further, the power receiving coil unit 140 includes a plurality of power receiving coils 141. The plurality of power receiving coils 141 are each electromagnetically inductively coupled to the corresponding power transmitting coils 131. The plurality of power receiving coils 141 are connected in series between the resonant capacitors 142a and 142b.

When each of the power transmitting coil unit 130 and the power receiving coil unit 140 includes a plurality of coils connected in series, a coil having a small inductance and a small size may be adopted as each of the plurality of coils. Accordingly, this increases the degree of freedom in the layout of the plurality of coils. Moreover, it becomes possible to feed high power.

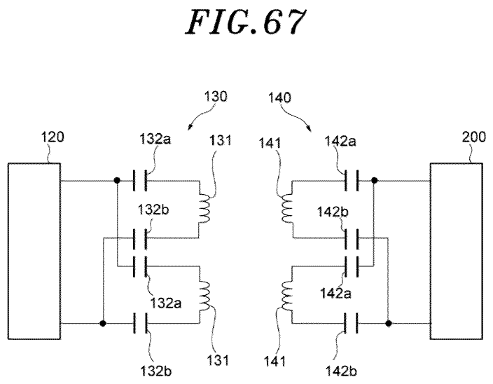

FIG. 66 is referred. FIG. 66 is a diagram illustrating a power receiving coil unit and a power transmitting coil unit in a plasma processing apparatus according to yet another exemplary embodiment. In the embodiment shown in FIG. 66, the power transmitting coil unit 130 includes the plurality of power transmitting coils 131. The plurality of power transmitting coils 131 are connected in parallel between the resonant capacitors 132a and 132b. Further, the power receiving coil unit 140 includes the plurality of power receiving coils 141. The plurality of power receiving coils 141 are each electromagnetically inductively coupled to the corresponding power transmitting coils 131. The plurality of power receiving coils 141 are connected in parallel between the resonant capacitors 142a and 142b.

FIG. 67 is referred. FIG. 67 is a diagram illustrating a power receiving coil unit and a power transmitting coil unit in a plasma processing apparatus according to yet another exemplary embodiment. In the embodiment shown in FIG. 67, the power transmitting coil unit 130 includes the plurality of power transmitting coils 131, a plurality of resonant capacitors 132a, and a plurality of resonant capacitors 132b. The plurality of power transmitting coils 131, the plurality of resonant capacitors 132a, and the plurality of resonant capacitors 132b configure a plurality of resonant circuits connected in parallel to the power transmission unit 120. Each of the plurality of resonant circuits is configured of a series connection of the resonant capacitor 132a, the power transmitting coil 131, and the resonant capacitor 132b.

In the embodiment shown in FIG. 67, the power receiving coil unit 140 includes the plurality of power receiving coils 141, a plurality of resonant capacitors 142a, and a plurality of resonant capacitors 142b. The plurality of power receiving coils 141 are each electromagnetically inductively coupled to the corresponding power transmitting coils 131. The plurality of power receiving coils 141, the plurality of resonant capacitors 142a, and the plurality of resonant capacitors 142b configure a plurality of resonant circuits connected in parallel to the RF filter 200. Each of the plurality of resonant circuits is configured of a series connection of the resonant capacitor 142a, the power receiving coil 141, and the resonant capacitor 142b.

In each of the embodiments in FIGS. 66 and 67, the power transmitting coil unit 130 and the power receiving coil unit 140 each include a plurality of coils connected in parallel, and have a plurality of resonant circuits each including the plurality of coils. In this manner, the plurality of resonant circuits may be configured separately, so that high power feeding efficiency is maintained. In addition, the degree of freedom in the layout of the plurality of coils is increased. Moreover, it becomes possible to feed high power.

### [Method of Storing Electricity in Electricity Storage Unit]

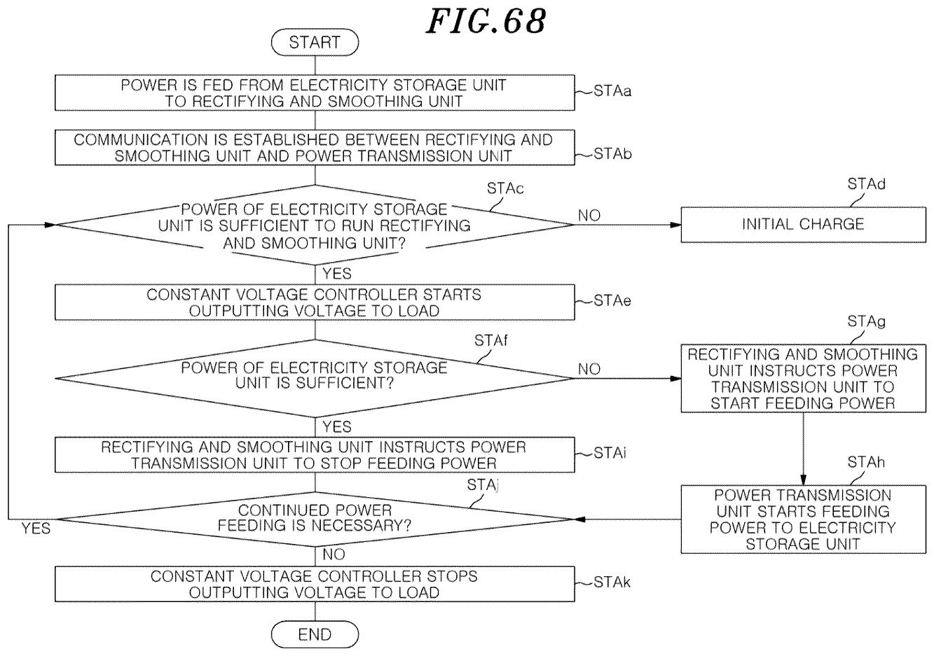

FIG. 68 is referred. FIG. 68 is a flowchart of an electricity storage method of an electricity storage unit according to one exemplary embodiment. In the plasma processing apparatuses according to various exemplary embodiments, electricity may be stored in the electricity storage unit 160 (or the electricity storage unit 160J) by the electricity storage method shown in FIG. 68.

The electricity storage unit 160 is mounted in advance in the plasma processing apparatus. Then, as shown in FIG. 68, the electricity storage method starts at process STAa. In the process STAa, power is fed from the mounted electricity storage unit 160 to the rectifying and smoothing unit 150. In the subsequent process STAb, communication is established between the rectifying and smoothing unit 150 and the power transmission unit 120.

In the subsequent process STAc, it is determined whether the power of the electricity storage unit 160 is sufficient to run the rectifying and smoothing unit 150. This determination may be made in the controller 152 of the rectifying and smoothing unit 150. When the power of the electricity storage unit 160 is insufficient to run the rectifying and smoothing unit 150, process STAd is performed. In the process STAd, the rectifying and smoothing unit 150 transmits an instruction signal to the power transmission unit 120, whereby the power transmission unit 120 starts feeding power, and the electricity storage unit 160 stores electricity (initial charging).

When the power of the electricity storage unit 160 is sufficient to run the rectifying and smoothing unit 150, process STAe is performed. In the process STAe, the constant voltage controller 180 starts outputting a voltage to a load such as the power consuming member 240.

In the subsequent process STAf, it is determined whether the power of the electricity storage unit 160 is sufficient to feed power to a load such as the power consuming member 240. This determination may be made in the controller 152 of the rectifying and smoothing unit 150. In process STAf, the power of the electricity storage unit 160 is determined to be insufficient when, for example, the power is equal to or lower than the above-mentioned first threshold value. When the power of the electricity storage unit 160 is insufficient, process STAg is performed. In the process STAg, the rectifying and smoothing unit 150 transmits an instruction signal to the power transmission unit 120 to instruct the power transmission unit 120 to feed power. In the subsequent process STAh, the power transmission unit 120 starts feeding power to the electricity storage unit 160. Thereafter, the processing proceeds to process STAj.

When it is determined in the process STAf that the power of the electricity storage unit 160 is sufficient, the rectifying and smoothing unit 150 transmits an instruction signal to the power transmission unit 120 to stop feeding power by the power transmission unit 120. In the process STAf, the power of the electricity storage unit 160 is determined to be sufficient when, for example, the power is greater than the above-mentioned second threshold value. Thereafter, the processing proceeds to process STAj.

In the process STAj, it is determined whether it is necessary to continue feeding power to a load such as the power consuming member 240. This determination may be made in the controller 152 of the rectifying and smoothing unit 150. When it is determined that it is necessary to continue feeding power to the load, the processing returns to process STAc. When it is determined that it is not necessary to continue feeding power to the load, the processing of the electricity storage method ends.

Although various exemplary embodiments have been described above, various additions, omissions, substitutions, and modifications may be made without being limited to the above-described exemplary embodiments. In addition, elements from different embodiments may be combined to form other embodiments.

Herein, various exemplary embodiments included in the present disclosure are described in [E1] to [E30] below.

### [E1]

A plasma processing apparatus comprising:
a plasma processing chamber;
a substrate support disposed within the plasma processing chamber;
an electrode or an antenna disposed outside a plasma processing space within the plasma processing chamber, the electrode or the antenna being disposed such that a space within the plasma processing chamber is located between the electrode or the antenna and the substrate support;
a high frequency power supply configured to generate high frequency power and electrically connected to the substrate support, the electrode or the antenna;
at least one power consuming member disposed within the plasma processing chamber or the substrate support;
at least one electricity storage unit electrically connected to the at least one power consuming member; and
at least one power receiving coil electrically connected to the at least one electricity storage unit and capable of receiving power from at least one power transmitting coil by electromagnetic induction coupling.

### [E2]

The plasma processing apparatus of E1, wherein the at least one power receiving coil is capable of receiving power from the at least one power transmitting coil by magnetic resonance.

### [E3]

The plasma processing apparatus of E1 or E2, wherein the at least one power receiving coil configures a filter having a characteristic of suppressing propagation of the high frequency power to the at least one power transmitting coil.

### [E4]

The plasma processing apparatus of any one of E1 to E3, further comprising a spacer formed of a dielectric material and provided between the at least one power receiving coil and a ground, the spacer providing a space stray capacitance between the at least one power receiving coil and the ground.

### [E5]

The plasma processing apparatus of any one of E1 to E4, further comprising at least one power transmitting coil electromagnetically inductively coupled to the at least one power receiving coil.

### [E6]

The plasma processing apparatus of any one of E1 to E5, wherein a distance between the at least one power receiving coil and the at least one power transmitting coil is set such that attenuation of the high frequency power between the at least one power receiving coil and the at least one power transmitting coil is −20 dB or less, and that the at least one power receiving coil is capable of receiving power from the at least one power transmitting coil.

### [E7]

The plasma processing apparatus of any one of E1 to E6, further comprising a rectifying and smoothing unit, the rectifying and smoothing unit comprising a rectifying circuit connected to the at least one power receiving coil, and a smoothing circuit connected between the rectifying circuit and the at least one electricity storage unit.

### [E8]

The plasma processing apparatus of E7, further comprising a power transmission unit electrically connected to the at least one power transmitting coil, the power transmission unit for supplying power to the at least one power transmitting coil, wherein the rectifying and smoothing unit comprises a controller configured to instruct the power transmission unit to supply power or stop supplying power depending on the power stored in the at least one electricity storage unit.

### [E9]

The plasma processing apparatus of E8, further comprising:
a signal line for an instruction signal instructing the supply of the power or the stop of supplying of the power, the signal line connecting the rectifying and smoothing unit and the power transmission unit; and
a filter connected between the rectifying and smoothing unit and the power transmission unit, the filter having a characteristic of suppressing propagation of the high frequency power via the signal line.

### [E10]

The plasma processing apparatus of E8, wherein:
each of the rectifying and smoothing unit and the power transmission unit comprises a communication unit;
the communication unit of the rectifying and smoothing unit and the communication unit of the power transmission unit are connected by wireless communication or optical fiber communication; and
the instruction signal instructing the supply of the power or the stop of supplying of the power is transmitted from the communication unit of the rectifying and smoothing unit to the communication unit of the power transmission unit by the wireless communication or the optical fiber communication.

### [E11]

The plasma processing apparatus of any one of E7 to E10, wherein the rectifying and smoothing unit and the at least one electricity storage unit are integrated.

### [E12]

The plasma processing apparatus of E11, further comprising:
a ground frame surrounding the substrate support together with the plasma processing chamber; and
an RF filter having a characteristic of suppressing the propagation of the high frequency power and connected between the at least one power receiving coil and the rectifying and smoothing unit,
wherein the rectifying and smoothing unit and the at least one electricity storage unit are disposed within a space surrounded by the ground frame.

### [E13]

The plasma processing apparatus of E11, further comprising:
a ground frame surrounding the substrate support together with the plasma processing chamber,
wherein the rectifying and smoothing unit and the at least one electricity storage unit are disposed outside a space surrounded by the ground frame. [E14]

The plasma processing apparatus of E13, further comprising an RF filter having a characteristic of suppressing the propagation of the high frequency power and configured to suppress the propagation of the high frequency power to the at least one power transmitting coil.

### [E15]

The plasma processing apparatus of any one of E7 to E10, further comprising:
a ground frame surrounding the substrate support together with the plasma processing chamber; and
an RF filter having a characteristic of suppressing the propagation of the high frequency power and connected between the at least one electricity storage unit and the rectifying and smoothing unit,
wherein:
the at least one electricity storage unit is disposed within a space surrounded by the ground frame; and
the rectifying and smoothing unit is disposed outside the space surrounded by the ground frame.

### [E16]

The plasma processing apparatus of any one of E7 to E10, further comprising:
a ground frame surrounding the substrate support together with the plasma processing chamber,
wherein:
the at least one electricity storage unit is disposed within a space surrounded by the ground frame; and
the rectifying and smoothing unit is disposed outside the space surrounded by the ground frame.

### [E17]

The plasma processing apparatus of E16, further comprising an RF filter having a characteristic of suppressing the propagation of the high frequency power and connected between the rectifying and smoothing unit and the at least one power receiving coil.

### [E18]

The plasma processing apparatus of any one of E7 to E10, wherein:
the at least one power transmitting coil, together with a first capacitor connected to one end thereof and a second capacitor connected to the other end thereof, configures a resonant circuit for transmission frequency of the power transmitted between the at least one power transmitting coil and the at least one power receiving coil;
the at least one power receiving coil, together with a third capacitor connected to one end thereof and a fourth capacitor connected to the other end thereof, configures a resonant circuit for the transmission frequency; and
the plasma processing apparatus further comprises an RF filter having a characteristic of suppressing the propagation of the high frequency power and connected between the rectifying and smoothing unit and the at least one power receiving coil,
wherein the RF filter comprises:
a first inductor comprising one end connected to the third capacitor and the other end connected to the rectifying and smoothing unit;
a second inductor comprising one end connected to the fourth capacitor and the other end connected to the rectifying and smoothing unit;
a fifth capacitor connected between the one end of the first inductor and a ground; and
a sixth capacitor connected between the one end of the second inductor and the ground.

### [E19]

The plasma processing apparatus of any one of E7 to E10, wherein:
the smoothing circuit comprises at least one capacitor connected between a positive line connecting the rectifying circuit and the at least one electricity storage unit and a negative line connecting the rectifying circuit and the at least one electricity storage unit; and
the smoothing circuit is configured to satisfy that a ratio of an amplitude of an output voltage of the smoothing circuit to an amplitude of the output voltage of the rectifying circuit is 3% or less, and a value obtained by dividing a cutoff frequency of the smoothing circuit by twice transmission frequency of the power transmitted between the at least one power transmitting coil and the at least one power receiving coil is smaller than 1/10.

### [E20]

The plasma processing apparatus of E19, wherein the smoothing circuit comprises a plurality of capacitors connected in parallel between the positive line and the negative line as the at least one capacitor.

### [E21]

The plasma processing apparatus of any one of E1 to E6, further comprising at least one voltage controller connected between the at least one electricity storage unit and the at least one power consuming member and configured to control application of a voltage to the at least one power consuming member and stop of the application.

### [E22]

The plasma processing apparatus of any one of E7 to E20, further comprising at least one voltage controller connected between the at least one electricity storage unit and the at least one power consuming member and configured to control application of a voltage to the at least one power consuming member and stop of the application.

### [E23]

The plasma processing apparatus of E22, further comprising:
a pulse generator configured to generate a synchronization pulse signal from an output voltage of the rectifying circuit, the synchronization pulse signal synchronized with the power transmitted between the at least one power transmitting coil and the at least one power receiving coil,
wherein the at least one voltage controller is configured to adjust timing of the application of the voltage to the at least one power consuming member and the stop of the application, based on the synchronization pulse signal.

### [E24]

The plasma processing apparatus of any one of E21 to E23, further comprising at least one voltage controlled converter, which is a DC-DC converter, connected between the at least one electricity storage unit and the at least one voltage controller.

### [E25]

The plasma processing apparatus of E24, wherein the at least one voltage controller, the at least one voltage controlled converter, and the at least one electricity storage unit are integrated.

### [E26]

The plasma processing apparatus of E24 or E25, wherein the at least one voltage controlled converter comprises:
a voltage detector configured to detect a voltage between a pair of outputs of the voltage controlled converter;
a drive circuit configured to switch between a voltage output of the voltage controlled converter and stop of the voltage output; and
a controller configured to control the drive circuit to stop the voltage output of the at least one voltage controlled converter when a value of the voltage detected by the voltage detector is equal to or greater than a threshold value.

### [E27]

The plasma processing apparatus of any one of E24 to E26, wherein the at least one voltage controlled converter comprises a plurality of voltage controlled converters connected in parallel between the at least one voltage controller and the at least one electricity storage unit.

### [E28]

The plasma processing apparatus of any one of E1 to E27, wherein:
the at least one power consuming member comprises a first power consuming member and a second power consuming member;
the at least one electricity storage unit comprises a first electricity storage unit connected to the first power consuming member and a second electricity storage unit connected to the second power consuming member;
the second power consuming member comprises a sensor; and
the second power consuming member is configured to receive power from the second electricity storage unit when an abnormality occurs in the plasma processing apparatus.

### [E29]

The plasma processing apparatus of E5, wherein the at least one power transmitting coil comprises a plurality of power transmitting coils, and the at least one power receiving coil comprises a plurality of power receiving coils respectively electromagnetically inductively coupled to the plurality of power transmitting coils.

### [E30]

The plasma processing apparatus of E29, wherein the plurality of power transmitting coils are connected in series or in parallel, and the plurality of power receiving coils are connected in series or in parallel.

From the foregoing, it will be understood that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A plasma processing apparatus comprising:
a plasma processing chamber;
a substrate support disposed within the plasma processing chamber;
an electrode or an antenna disposed outside a plasma processing space within the plasma processing chamber, the electrode or the antenna being disposed such that a space within the plasma processing chamber is located between the electrode or the antenna and the substrate support;
a high frequency power supply configured to generate high frequency power and electrically connected to the substrate support, the electrode or the antenna;
at least one power consuming member disposed within the plasma processing chamber or the substrate support;
at least one electricity storage unit electrically connected to the at least one power consuming member; and
at least one power receiving coil electrically connected to the at least one electricity storage unit and capable of receiving power from at least one power transmitting coil by electromagnetic induction coupling.

2. The plasma processing apparatus of claim 1, wherein the at least one power receiving coil is capable of receiving power from the at least one power transmitting coil by magnetic resonance.

3. The plasma processing apparatus of claim 1, wherein the at least one power receiving coil configures a filter having a characteristic of suppressing propagation of the high frequency power to the at least one power transmitting coil.

4. The plasma processing apparatus of claim 3, further comprising a spacer formed of a dielectric material and provided between the at least one power receiving coil and a ground, the spacer providing a space stray capacitance between the at least one power receiving coil and the ground.

5. The plasma processing apparatus of claim 4, further comprising at least one power transmitting coil electromagnetically inductively coupled to the at least one power receiving coil.

6. The plasma processing apparatus of claim 5, wherein a distance between the at least one power receiving coil and the at least one power transmitting coil is set such that attenuation of the high frequency power between the at least one power receiving coil and the at least one power transmitting coil is-20 dB or less, and that the at least one power receiving coil is capable of receiving power from the at least one power transmitting coil.

7. The plasma processing apparatus of claim 1, further comprising a rectifying and smoothing unit, the rectifying and smoothing unit comprising a rectifying circuit connected to the at least one power receiving coil, and a smoothing circuit connected between the rectifying circuit and the at least one electricity storage unit.

8. The plasma processing apparatus of claim 7, further comprising a power transmission unit electrically connected to the at least one power transmitting coil, the power transmission unit for supplying power to the at least one power transmitting coil,
wherein the rectifying and smoothing unit comprises a controller configured to instruct the power transmission unit to supply power or stop supplying power depending on the power stored in the at least one electricity storage unit.

9. The plasma processing apparatus of claim 8, further comprising:
a signal line for an instruction signal instructing the supply of the power or the stop of supplying of the power, the signal line connecting the rectifying and smoothing unit and the power transmission unit; and
a filter connected between the rectifying and smoothing unit and the power transmission unit, the filter having a characteristic of suppressing propagation of the high frequency power via the signal line.

10. The plasma processing apparatus of claim 8, wherein:
each of the rectifying and smoothing unit and the power transmission unit comprises a communication unit;
the communication unit of the rectifying and smoothing unit and the communication unit of the power transmission unit are connected by wireless communication or optical fiber communication; and
the instruction signal instructing the supply of the power or the stop of supplying of the power is transmitted from the communication unit of the rectifying and smoothing unit to the communication unit of the power transmission unit by the wireless communication or the optical fiber communication.

11. The plasma processing apparatus of claim 7, wherein the rectifying and smoothing unit and the at least one electricity storage unit are integrated.

12. The plasma processing apparatus of claim 11, further comprising:
a ground frame surrounding the substrate support together with the plasma processing chamber; and
an RF filter having a characteristic of suppressing the propagation of the high frequency power and connected between the at least one power receiving coil and the rectifying and smoothing unit,
wherein the rectifying and smoothing unit and the at least one electricity storage unit are disposed within a space surrounded by the ground frame.

13. The plasma processing apparatus of claim 11, further comprising:
a ground frame surrounding the substrate support together with the plasma processing chamber,
wherein the rectifying and smoothing unit and the at least one electricity storage unit are disposed outside a space surrounded by the ground frame.

14. The plasma processing apparatus of claim 13, further comprising an RF filter having a characteristic of suppressing the propagation of the high frequency power and configured to suppress the propagation of the high frequency power to the at least one power transmitting coil.

15. The plasma processing apparatus of claim 7, further comprising:
a ground frame surrounding the substrate support together with the plasma processing chamber; and
an RF filter having a characteristic of suppressing the propagation of the high frequency power and connected between the at least one electricity storage unit and the rectifying and smoothing unit,
wherein:
the at least one electricity storage unit is disposed within a space surrounded by the ground frame; and
the rectifying and smoothing unit is disposed outside the space surrounded by the ground frame.

16. The plasma processing apparatus of claim 7, further comprising:
a ground frame surrounding the substrate support together with the plasma processing chamber,
wherein:
the at least one electricity storage unit is disposed within a space surrounded by the ground frame; and
the rectifying and smoothing unit is disposed outside the space surrounded by the ground frame.

17. The plasma processing apparatus of claim 16, further comprising an RF filter having a characteristic of suppressing the propagation of the high frequency power and connected between the rectifying and smoothing unit and the at least one power receiving coil.

18. The plasma processing apparatus of claim 7, wherein:
the at least one power transmitting coil, together with a first capacitor connected to one end thereof and a second capacitor connected to the other end thereof, configures a resonant circuit for transmission frequency of the power transmitted between the at least one power transmitting coil and the at least one power receiving coil;
the at least one power receiving coil, together with a third capacitor connected to one end thereof and a fourth capacitor connected to the other end thereof, configures a resonant circuit for the transmission frequency; and
the plasma processing apparatus further comprises an RF filter having a characteristic of suppressing the propagation of the high frequency power and connected between the rectifying and smoothing unit and the at least one power receiving coil,
wherein the RF filter comprises:
a first inductor comprising one end connected to the third capacitor and the other end connected to the rectifying and smoothing unit;
a second inductor comprising one end connected to the fourth capacitor and the other end connected to the rectifying and smoothing unit;
a fifth capacitor connected between the one end of the first inductor and a ground; and
a sixth capacitor connected between the one end of the second inductor and the ground.

19. The plasma processing apparatus of claim 7, wherein:
the smoothing circuit comprises at least one capacitor connected between a positive line connecting the rectifying circuit and the at least one electricity storage unit and a negative line connecting the rectifying circuit and the at least one electricity storage unit; and
the smoothing circuit is configured to satisfy that a ratio of an amplitude of an output voltage of the smoothing circuit to an amplitude of the output voltage of the rectifying circuit is 3% or less, and a value obtained by dividing a cutoff frequency of the smoothing circuit by twice transmission frequency of the power transmitted between the at least one power transmitting coil and the at least one power receiving coil is smaller than 1/10.

20. The plasma processing apparatus of claim 19, wherein the smoothing circuit comprises a plurality of capacitors connected in parallel between the positive line and the negative line as the at least one capacitor.

21. The plasma processing apparatus of claim 1, further comprising at least one voltage controller connected between the at least one electricity storage unit and the at least one power consuming member and configured to control application of a voltage to the at least one power consuming member and stop of the application.

22. The plasma processing apparatus of claim 7, further comprising at least one voltage controller connected between the at least one electricity storage unit and the at least one power consuming member and configured to control application of a voltage to the at least one power consuming member and stop of the application.

23. The plasma processing apparatus of claim 22, further comprising:
a pulse generator configured to generate a synchronization pulse signal from an output voltage of the rectifying circuit, the synchronization pulse signal synchronized with the power transmitted between the at least one power transmitting coil and the at least one power receiving coil,
wherein the at least one voltage controller is configured to adjust timing of the application of the voltage to the at least one power consuming member and the stop of the application, based on the synchronization pulse signal.

24. The plasma processing apparatus of claim 21, further comprising at least one voltage controlled converter, which is a DC-DC converter, connected between the at least one electricity storage unit and the at least one voltage controller.

25. The plasma processing apparatus of claim 24, wherein the at least one voltage controller, the at least one voltage controlled converter, and the at least one electricity storage unit are integrated.

26. The plasma processing apparatus of claim 24, wherein the at least one voltage controlled converter comprises:
a voltage detector configured to detect a voltage between a pair of outputs of the voltage controlled converter;
a drive circuit configured to switch between a voltage output of the voltage controlled converter and stop of the voltage output; and
a controller configured to control the drive circuit to stop the voltage output of the at least one voltage controlled converter when a value of the voltage detected by the voltage detector is equal to or greater than a threshold value.

27. The plasma processing apparatus of claim 24, wherein the at least one voltage controlled converter comprises a plurality of voltage controlled converters connected in parallel between the at least one voltage controller and the at least one electricity storage unit.

28. The plasma processing apparatus of claim 1, wherein:
the at least one power consuming member comprises a first power consuming member and a second power consuming member;
the at least one electricity storage unit comprises a first electricity storage unit connected to the first power consuming member and a second electricity storage unit connected to the second power consuming member;
the second power consuming member comprises a sensor; and
the second power consuming member is configured to receive power from the second electricity storage unit when an abnormality occurs in the plasma processing apparatus.

29. The plasma processing apparatus of claim 5, wherein the at least one power transmitting coil comprises a plurality of power transmitting coils, and the at least one power receiving coil comprises a plurality of power receiving coils respectively electromagnetically inductively coupled to the plurality of power transmitting coils.

30. The plasma processing apparatus of claim 29, wherein the plurality of power transmitting coils are connected in series or in parallel, and the plurality of power receiving coils are connected in series or in parallel.
